(19) United States
(12) Patent Application Publication
(10) Pub. No.: US 2026/0281219 A1
(43) Pub. Date: Sep. 17, 2026

(54) ELECTRONIC DEVICE

(71) Applicant: Samsung Electronics Co., Ltd., Suwon-si (KR)

(72) Inventors: Sanghyeon KIM, Suwon-si (KR); Ohhee LEE, Suwon-si (KR)

(21) Appl. No.: 19/682,995

(22) Filed: May 20, 2026

Related U.S. Application Data
(63) Continuation of application No. PCT/KR2024/020886, filed on Dec. 20, 2024.

(30) Foreign Application Priority Data
Dec. 29, 2023 (KR) 10-2023-0196084
Jan. 11, 2024 (KR) 10-2024-0004823

(51) Int. Cl. H04M 1/02; G06F 1/16; G06F 1/30

(52) U.S. Cl. CPC H04M 1/0237; G06F 1/1656; G06F 1/305; H04M 1/0268; H04M 1/0277

(57) ABSTRACT

An electronic device is provided. The electronic device includes a housing including a first housing and a second housing, the second housing being configured to movably engage with the first housing between a retracted position and an extended position, a display assembly coupled to the first housing and the second housing, wherein a size of an area of the display assembly visible from a front side of the housing changes as the second housing moves between the retracted position and the extended position, wherein the display assembly includes (i) an extended portion that is exposed in the extended position and obscured in the retracted position, and (ii) a fixed portion connected to the extended portion, the fixed portion being fixedly exposed, a first case disposed toward one side of the housing, the first case including a case groove, and a structure disposed within the case groove, the structure being disposed toward at least a portion of a display curved area of the display assembly, wherein the structure includes a structure substrate located within the case groove, a support structure disposed toward one side of the structure substrate, and a plurality of actuators at least partially disposed on the structure substrate, the plurality of actuators being configured to move the support structure in a first direction toward the display curved area or in a second direction opposite to the first direction.

### CROSS-REFERENCE TO RELATED APPLICATION(S)

This application is a continuation application, claiming priority under 35 U.S.C. § 365 (c), of an International application No. PCT/KR2024/020886, filed on Dec. 20, 2024, which is based on and claims the benefit of a Korean patent application number 10-2023-0196084, filed on Dec. 29, 2023, in the Ministry of Intellectual Property (MOIP), and of a Korean patent application number 10-2024-0004823, filed on Jan. 11, 2024, in the Ministry of Intellectual Property (MOIP), the disclosure of each of which is incorporated by reference herein in its entirety.

### BACKGROUND

### 1. Field

The disclosure relates to an electronic device.

### 2. Description of Related Art

A portable electronic device, such as a smartphone, may provide various functions, including call functions, based on various types of applications. In providing the various functions, the portable electronic device may output a screen corresponding to each function. When the user uses the various functions, the user may want to use a wider screen. However, in a general portable electronic device, when a display is increased in size to display a screen, an overall size thereof increases, so that portability may deteriorate. Accordingly, a portable electronic device that may increase a size of a screen while maintaining portability has been developed.

The above information is presented as background information only to assist with an understanding of the disclosure. No determination has been made, and no assertion is made, as to whether any of the above might be applicable as prior art with regard to the disclosure.

### SUMMARY

Aspects of the disclosure are to address at least the above-mentioned problems and/or disadvantages and to provide at least the advantages described below. Accordingly, an aspect of the disclosure is to provide an electronic device.

Additional aspects will be set forth in part in the description which follows and, in part, will be apparent from the description, or may be learned by practice of the presented embodiments.

In accordance with an aspect of the disclosure, an electronic device is provided. The electronic device includes a housing including a first housing and a second housing, the second housing being configured to movably engage with the first housing between a retracted position and an extended position, a display assembly coupled to the first housing and the second housing, wherein a size of an area of the display assembly visible from a front side of the housing changes as the second housing moves between the retracted position and the extended position, wherein the display assembly includes (i) an extended portion that is exposed in the extended position and obscured in the retracted position, and (ii) a fixed portion connected to the extended portion, the fixed portion being fixedly exposed, a first case disposed toward one side of the housing, the first case including a case groove, and a structure disposed within the case groove, the structure being disposed toward at least a portion of a display curved area of the display assembly, wherein the structure includes a structure substrate located within the case groove, a support structure disposed toward one side of the structure substrate, and a plurality of actuators at least partially disposed on the structure substrate, the plurality of actuators being configured to move the support structure in a first direction toward the display curved area or in a second direction opposite to the first direction.

Other aspects, advantages, and salient features of the disclosure will become apparent to those skilled in the art from the following detailed description, which, taken in conjunction with the annexed drawings, discloses various embodiments of the disclosure.

### BRIEF DESCRIPTION OF THE DRAWINGS

The above and other aspects, features, and advantages of certain embodiments of the disclosure will be more apparent from the following description taken in conjunction with the accompanying drawings, in which:

FIG. 1 is a block diagram of an electronic device in a network environment, according to an embodiment of the disclosure;

FIG. 2 is a view illustrating an example of a first state of an electronic device according to an embodiment of the disclosure;

FIG. 3 is a view illustrating an example of a second state of an electronic device according to an embodiment of the disclosure;

FIG. 4 is an exploded perspective view illustrating an electronic device according to an embodiment of the disclosure;

FIG. 5 is a view illustrating an example of a first case and a first-type auxiliary structure according to an embodiment of the disclosure;

FIG. 6 is a view illustrating an example of a structure substrate of a first-type auxiliary structure according to an embodiment of the disclosure;

FIG. 7 is a view illustrating an example of a support structure of a first-type auxiliary structure according to an embodiment of the disclosure;

FIG. 8 is a view illustrating an example of an actuator of a first-type auxiliary structure according to an embodiment of the disclosure;

FIG. 9 is a view illustrating a first arrangement state of an electronic device according to an embodiment of the disclosure;

FIG. 10 is a view illustrating a second arrangement state of an electronic device according to an embodiment of the disclosure;

FIG. 11 is a view illustrating an example of a second-type auxiliary structure according to an embodiment of the disclosure;

FIG. 12 is a view illustrating an example of an electronic device including a third-type auxiliary structure according to an embodiment of the disclosure;

FIG. 13 is a view illustrating an example of an electronic device including a fifth-type auxiliary structure according to an embodiment of the disclosure;

FIG. 14 is a view illustrating an example of a first printed circuit board connected to an auxiliary structure according to an embodiment of the disclosure;

FIG. 15 is a view illustrating an example of a connection relationship of a first printed circuit board and other printed circuit boards according to an embodiment of the disclosure;

FIG. 16 is a view illustrating a first state related to sensing of sliding of an electronic device according to an embodiment of the disclosure; and

FIG. 17 is a view illustrating a second state related to sensing of sliding of an electronic device according to an embodiment of the disclosure.

Throughout the drawings, it should be noted that like reference numbers are used to depict the same or similar elements, features, and structures.

### DETAILED DESCRIPTION

The following description with reference to the accompanying drawings is provided to assist in a comprehensive understanding of various embodiments of the disclosure as defined by the claims and their equivalents. It includes various specific details to assist in that understanding but these are to be regarded as merely exemplary. Accordingly, those of ordinary skill in the art will recognize that various changes and modifications of the various embodiments described herein can be made without departing from the scope and spirit of the disclosure. In addition, descriptions of well-known functions and constructions may be omitted for clarity and conciseness.

The terms and words used in the following description and claims are not limited to the bibliographical meanings, but, are merely used by the inventor to enable a clear and consistent understanding of the disclosure. Accordingly, it should be apparent to those skilled in the art that the following description of various embodiments of the disclosure is provided for illustration purpose only and not for the purpose of limiting the disclosure as defined by the appended claims and their equivalents.

It is to be understood that the singular forms “a,” “an,” and “the” include plural referents unless the context clearly dictates otherwise. Thus, for example, reference to “a component surface” includes reference to one or more of such surfaces.

An embodiment of the disclosure described below may provide an electronic device that is capable of preventing damage to at least a portion of a display caused by an external impact (e.g., an impact caused by a drop or another external impact), when the electronic device (e.g., a rollable electronic device or a slidable electronic device) is in a retracted position or an extended position. As an example, the electronic device of the disclosure may include a structure that is additionally disposed on one side of the first case to protect a display (or a display assembly), so that the display may be stably supported, the display may be protected when an external impact occurs, and the impact may be dispersed.

The objects according to various embodiments of the disclosure will be described as necessary in a process of describing the embodiments.

It should be appreciated that the blocks in each flowchart and combinations of the flowcharts may be performed by one or more computer programs which include instructions. The entirety of the one or more computer programs may be stored in a single memory device or the one or more computer programs may be divided with different portions stored in different multiple memory devices.

Any of the functions or operations described herein can be processed by one processor or a combination of processors. The one processor or the combination of processors is circuitry performing processing and includes circuitry like an application processor (AP, e.g. a central processing unit (CPU)), a communication processor (CP, e.g., a modem), a graphics processing unit (GPU), a neural processing unit (NPU) (e.g., an artificial intelligence (AI) chip), a wireless fidelity (Wi-Fi) chip, a Bluetooth® chip, a global positioning system (GPS) chip, a near field communication (NFC) chip, connectivity chips, a sensor controller, a touch controller, a finger-print sensor controller, a display driver integrated circuit (IC), an audio CODEC chip, a universal serial bus (USB) controller, a camera controller, an image processing IC, a microprocessor unit (MPU), a system on chip (SoC), an IC, or the like.

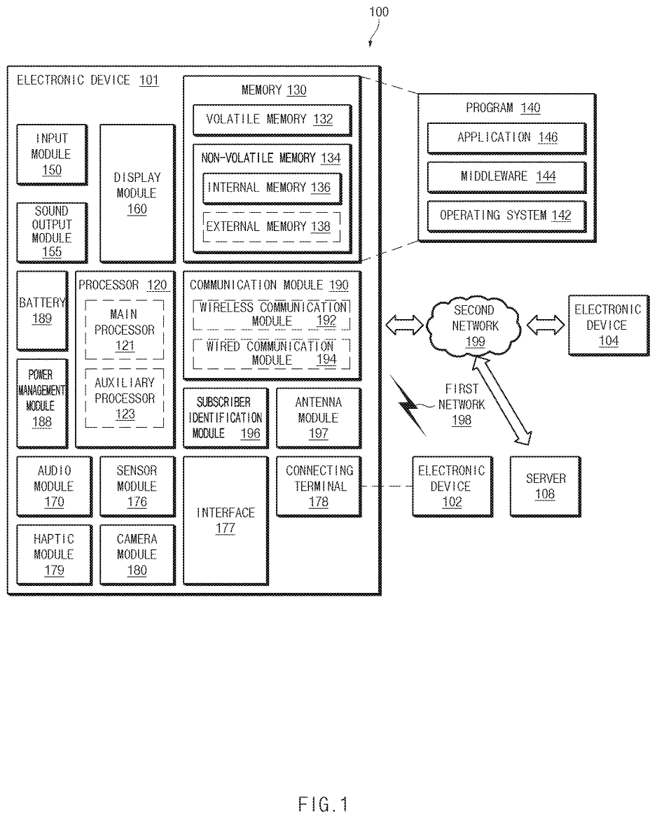

FIG. 1 is a block diagram illustrating an electronic device in a network environment according to an embodiment of the disclosure.

Referring to FIG. 1, an electronic device 101 (e.g., the electronic device 101 of FIG. 1) in a network environment 100 may communicate with an electronic device 102 via a first network 198 (e.g., a short-range wireless communication network), or an electronic device 104 or a server 108 via a second network 199 (e.g., a long-range wireless communication network). According to an embodiment, the electronic device 101 may communicate with the electronic device 104 via the server 108. According to an embodiment, the electronic device 101 may include a processor 120, a memory 130, an input module 150, a sound output module 155, a display module 160, an audio module 170, a sensor module 176, an interface 177, a connecting terminal 178, a haptic module 179, a camera module 180, a power management module 188, a battery 189, a communication module 190, a subscriber identification module (SIM) 196, or an antenna module 197. In some embodiments, at least one (e.g., the connecting terminal 178) of the components may be omitted from the electronic device 101, or one or more other components may be added in the electronic device 101. In some embodiments, some of the components may be implemented as single integrated circuitry. For example, some (e.g., the sensor module 176, the camera module 180, or the antenna module 197) of the components may be integrated into a single component (e.g., the display module 160).

The processor 120 may execute, for example, software (e.g., a program 140) to control at least one other component (e.g., a hardware or software component) of the electronic device 101 coupled with the processor 120, and may perform various data processing or computation. According to one embodiment, as at least part of the data processing or computation, the processor 120 may load a command or data received from another component (e.g., the sensor module 176 or the communication module 190) in a volatile memory 132, process the command or the data stored in the volatile memory 132, and store resulting data in a non-volatile memory 134. According to an embodiment, the processor 120 may include a main processor 121 (e.g., a central processing unit (CPU) or an application processor (AP)), and an auxiliary processor 123 (e.g., a graphics processing unit (GPU), a neural processing unit (NPU), an image signal processor (ISP), a sensor hub processor, or a communication processor (CP)) that is operable independently from, or in conjunction with, the main processor 121. When the electronic device 101 includes the main processor 121 and the auxiliary processor, the auxiliary processor 123 may be adapted to consume less power than the main processor 121, or to be specific to a specified function. The auxiliary processor 123 may be implemented as separate from, or as part of the main processor 121.

The auxiliary processor 123 may control at least some of functions or states related to at least one component (e.g., the display module 160, the sensor module 176, or the communication module 190) among the components of the electronic device 101, instead of the main processor 121 while the main processor 121 is in an inactive (e.g., sleep) state, or together with the main processor 121 while the main processor 121 is in an active state (e.g., executing an application). According to an embodiment, the auxiliary processor 123 (e.g., an image signal processor or a communication processor) may be implemented as part of another component (e.g., the camera module 180 or the communication module 190) functionally related to the auxiliary processor 123. According to an embodiment, the auxiliary processor 123 (e.g., a neural network processing device) may include a hardware structure specified for processing an artificial intelligence (AI) model. The AI model may be generated through machine learning. The learning may be performed by the electronic device 101 performing the AI, and may be performed through an additional server (e.g., the server 108). A learning algorithm may include, for example, a supervised learning algorithm, an unsupervised learning algorithm, a semi-supervised learning algorithm, or a reinforcement learning algorithm, but the disclosure is not limited thereto. The AI model may include a plurality of artificial neural network (ANN) layers. The ANN may include a deep neural network (DNN), a convolutional neural network (CNN), a recurrent neural network (RNN), a restricted Boltzmann machine (RBM), a deep belief network (DBN), a bidirectional recurrent deep neural network (BRDNN), a deep Q-networks or the combination of the above networks, but the disclosure is not limited thereto. The AI model may additionally or alternatively include a software structure, in addition to a hardware structure.

The memory 130 may store various data used by at least one component (e.g., the processor 120 or the sensor module 176) of the electronic device 101. The various data may include, for example, software (e.g., the program 140) and input data or output data for a command related thereto. The memory 130 may include the volatile memory 132 or the non-volatile memory 134.

The program 140 may be stored in the memory 130 as software, and may include, for example, an operating system (OS) 142, middleware 144, or an application 146.

The input module 150 may receive a command or data to be used by other component (e.g., the processor 120) of the electronic device 101, from the outside (e.g., a user) of the electronic device 101. The input module 150 may include, for example, a microphone, a mouse, a keyboard, a key (e.g., a button), or a digital pen (e.g., a stylus pen).

The sound output module 155 may output sound signals to the outside of the electronic device 101. The sound output module 155 may include, for example, a speaker or a receiver. The speaker may be used for general purposes, such as playing multimedia or playing record, and the receiver may be used for an incoming call. According to an embodiment, the receiver may be implemented as separate from, or as part of the speaker.

The display module 160 may visually provide information to the outside (e.g., a user) of the electronic device 101. The display module 160 may include, for example, a display, a hologram device, or a projector and control circuitry to control a corresponding one of the display, hologram device, and projector. According to an embodiment, the display module 160 may include touch sensor adapted to detect a touch, or a pressure sensor adapted to measure the intensity of force incurred by the touch.

The audio module 170 may convert a sound into an electrical signal and vice versa. According to an embodiment, the audio module 170 may obtain the sound via the input module 150, or output the sound via the sound output module 155 or an external electronic device (e.g., the electronic device 102) (e.g., speaker of headphone) directly (e.g., wiredly) or wirelessly coupled with the electronic device 101.

The sensor module 176 may detect an operational state (e.g., power or temperature) of the electronic device 101 or an environmental state (e.g., a state of a user) external to the electronic device 101, and then generate an electrical signal or data value corresponding to the detected state. According to an embodiment, the sensor module 176 may include, for example, a gesture sensor, a gyro sensor, an atmospheric pressure sensor, a magnetic sensor, an acceleration sensor, a grip sensor, a proximity sensor, a color sensor, an infrared (IR) sensor, a biometric sensor, a temperature sensor, a humidity sensor, or an illuminance sensor.

The interface 177 may support one or more specified protocols to be used for the electronic device 101 to be coupled with the external electronic device (e.g., the electronic device 102) directly (e.g., wiredly) or wirelessly. According to an embodiment, the interface 177 may include, for example, a high definition multimedia interface (HDMI), a universal serial bus (USB) interface, a secure digital (SD) card interface, or an audio interface.

A connecting terminal 178 may include a connector via which the electronic device 101 may be physically connected with the external electronic device (e.g., the electronic device 102). According to an embodiment, the connecting terminal 178 may include, for example, a HDMI connector, a USB connector, a SD card connector, or an audio connector (e.g., a headphone connector).

The haptic module 179 may convert an electrical signal into a mechanical stimulus (e.g., a vibration or a movement) or electrical stimulus which may be recognized by a user via his tactile sensation or kinesthetic sensation. According to an embodiment, the haptic module 179 may include, for example, a motor, a piezoelectric element, or an electric stimulator.

The camera module 180 may capture a still image or moving images. According to an embodiment, the camera module 180 may include one or more lenses, image sensors, image signal processors, or flashes.

The power management module 188 may manage power supplied to the electronic device 101. According to one embodiment, the power management module 188 may be implemented as at least part of, for example, a power management integrated circuit (PMIC).

The battery 189 may supply power to at least one component of the electronic device 101. According to an embodiment, the battery 189 may include, for example, a primary cell which is not rechargeable, a secondary cell which is rechargeable, or a fuel cell.

The communication module 190 may support establishing a direct (e.g., wired) communication channel or a wireless communication channel between the electronic device 101 and the external electronic device (e.g., the electronic device 102, the electronic device 104, or the server 108) and performing communication via the established communication channel. The communication module 190 may include one or more communication processors that are operable independently from the processor 120 (e.g., the application processor (AP)) and supports a direct (e.g., wired) communication or a wireless communication. According to an embodiment, the communication module 190 may include a wireless communication module 192 (e.g., a cellular communication module, a short-range wireless communication module, or a global navigation satellite system (GNSS) communication module) or a wired communication module 194 (e.g., a local area network (LAN) communication module or a power line communication (PLC) module). The communication module according to an embodiment may communicate with the external electronic device 104 via the first network 198 (e.g., a short-range communication network, such as Bluetooth™, wireless-fidelity (Wi-Fi) direct, or infrared data association (IrDA)) or the second network 199 (e.g., a long-range communication network, such as a legacy cellular network, fifth generation (5G) network, next generation communication network, the Internet, or a computer network (e.g., LAN or wide area network (WAN)). These various types of communication modules may be implemented as a single component (e.g., a single chip), or may be implemented as multi components (e.g., multi chips) separate from each other. The wireless communication module 192 may identify or authenticate the electronic device 101 in a communication network, such as the first network 198 or the second network 199, using subscriber information (e.g., international mobile subscriber identity (IMSI)) stored in the subscriber identification module 196.

The wireless communication module 192 may support a 5G network and a next-generation communication technology, for example, a new radio (NR) access technology after a fourth generation (4G) network. The NR access technology may support high-speed transmission for high capacity data (enhanced mobile broadband; eMBB), terminal power minimizing and multiple terminal access (massive machine type communication; mMTC), or ultra-reliable and low-latency communications (URLLC). The wireless communication module 192 may support a high-frequency band (e.g., millimeter wave (mmWave) band) to achieve, for example, a higher data rate. The wireless communication module 192 may support various technologies, for example, beamforming, massive multiple-input and multiple-output (MIMO), Full-dimensional MIMO, an array antenna, analog beam-forming, or a large-scale antenna, to secure performance in high frequency bands. The wireless communication module 192 may support various requirements defined in the electronic device 101, the external electronic device (e.g., the electronic device 104) or the network system (e.g., the second network 199). According to one embodiment, the wireless communication module 192 may support a peak data rate (e.g., 20 Gbps or more) for eMBB realization, loss coverage (e.g., 164 dB or less) for mMTC realization, or user plane (U-plane) latency (e.g., 0.5 ms or less, or the round trip of 1 ms or less in each of a downlink (DL) and an uplink (UL)) for URLCC realization.

The antenna module 197 may transmit or receive a signal or power to or from the outside (e.g., the external electronic device) of the electronic device 101. According to an embodiment, the antenna module 197 may include an antenna including a radiating element composed of a conductive material or a conductive pattern formed in or on a substrate (e.g., PCB). According to an embodiment, the antenna module 197 may include a plurality of antennas (e.g., an array antenna). In such a case, at least one antenna appropriate for a communication scheme used in the communication network, such as the first network 198 or the second network 199, may be selected, for example, by the communication module 190 from the plurality of antennas. The signal or the power may then be transmitted or received between the communication module 190 and the external electronic device via the selected at least one antenna. According to an embodiment, another component (e.g., a radio frequency integrated circuit (RFIC)) other than the radiating element may be additionally formed as part of the antenna module 197.

According to an embodiment, the antenna module 197 may form an mmWave antenna module. According to an embodiment, the mm Wave antenna module may include a printed circuit board, an RFIC disposed on a first surface (e.g., a bottom surface) of the printed circuit board, or disposed adjacent to the first surface to support the specific high frequency band (e.g., mmWave band), and a plurality of antennas (e.g., an array antenna) disposed on a second surface (e.g., a top surface or a side surface) of the printed circuit board or disposed adjacent to the second surface to transmit or receive a signal having the specified high frequency band.

At least some of the above-described components may be coupled mutually and communicate signals (e.g., commands or data) therebetween via an inter-peripheral communication scheme (e.g., a bus, general purpose input and output (GPIO), serial peripheral interface (SPI), or mobile industry processor interface (MIPI)).

According to an embodiment, the command or data may be transmitted or received between the electronic device 101 and the external electronic device 104 through the server 108 connected to the second network 199. Each of the external electronic device 102 or 104 may be a device of which the type is the same as or different from that of the electronic device 101. According to an embodiment, all or a part of operations to be executed by the electronic device 101 may be executed in one or more external electronic devices among the external electronic devices 102, 104, or 108. For example, when the electronic device 101 needs to perform any function or service automatically or in response to a request from the user or any other device, the electronic device 101 may additionally request one or more external electronic devices to perform at least part of the function or service, instead of internally executing the function or service. The one or more external electronic devices which receive the request may execute at least a part of the function or service thus requested or an additional function or service associated with the request, and may provide a result of the execution to the electronic device 101. The electronic device 101 may process the result as it is or additionally, and may provide a result of the processing as at least a part of the response to the request. To this end, for example, cloud computing, distributed computing, mobile edge computing (MEC), or client-server computing may be used. For example, the electronic device 101 may provide an ultra-low latency service by using distributed computing or mobile edge computing. In another embodiment, the external electronic device 104 may include an Internet of Things (IoT) device. The server 108 may be an intelligent server using machine learning and/or a neural network. According to an embodiment, the external electronic device 104 or the server 108 may be included in the second network 199. The electronic device 101 may be applied to an intelligent service (e.g., a smart home, a smart city, a smart car, or a healthcare) based on 5G communication technology and IoT-related technology.

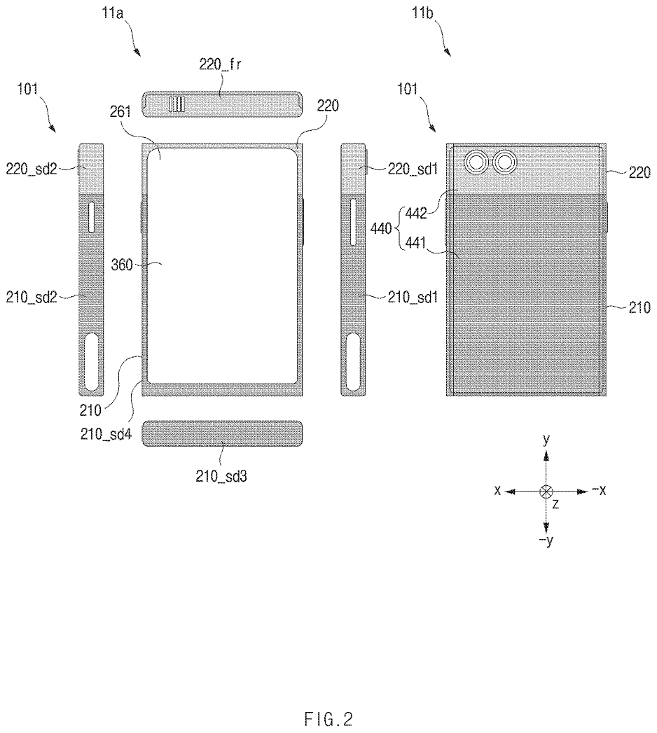

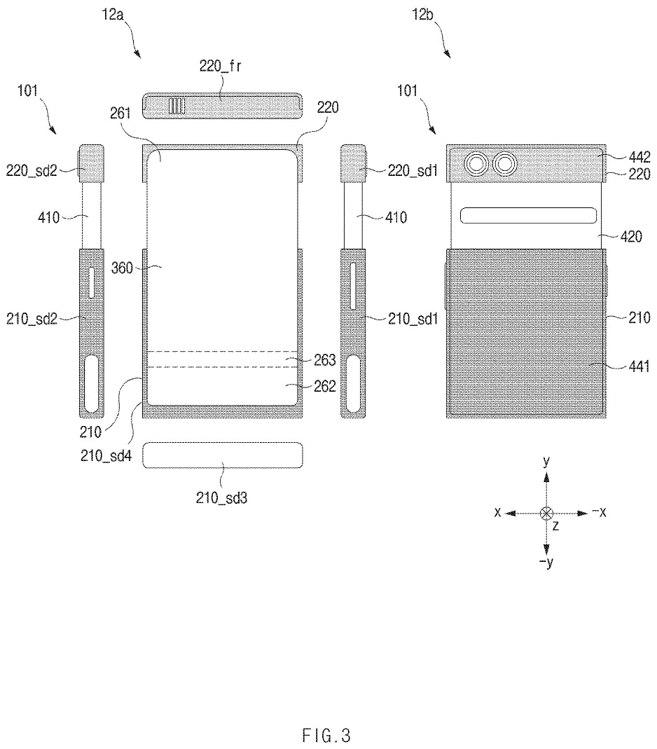

FIG. 2 is a view illustrating an example of a first state of an electronic device according to an embodiment of the disclosure. FIG. 3 is a view illustrating an example of a second state of an electronic device according to an embodiment of the disclosure. As an example, state 11a of FIG. 2 corresponds to a view illustrating an example of a front surface and a side surface of the electronic device at a retracted position, and state 11b of FIG. 2 corresponds to a view illustrating an example of a rear surface of the electronic device at an extended position. State 12a of FIG. 3 corresponds to a view illustrating an example of a front surface and a side surface of the electronic device at an extended position, and state 12b of FIG. 3 corresponds to a view illustrating an example of a rear surface of the electronic device at a retracted position.

Referring to FIGS. 2 and 3, the electronic device 101 according to an embodiment may include a first case 210 (or a base housing, a base structure, or a first cover), a second case 220 (or a front housing, a front decorative member, a front frame, or a second cover), a first housing 410 (or a movable housing, a slide plate, a slide housing, a slide structure, a slide case, a slide body, a slide frame, a slide bracket, or a first frame), a second housing 420 (or a second frame, a fixed plate, a fixed housing, a fixed frame, or a fixed bracket), and a display assembly 360.

In an embodiment, the electronic device 101 may be an electronic device of a slidable type or a rollable type, and a state thereof may be changed by movement (or movement of a first housing 410 with respect to a second housing 420) of a second case 220 with respect to a first case 210. For example, the state of the electronic device 101 may include state 11a and state 11b (e.g., a retracted position, a closed mode, a reduced mode, a slide-in mode, or a minimum size mode) and state 12a and state 12b (e.g., an extended position, an open mode, an expanded mode, a slide-out mode, or a maximum size mode). State 11a and state 11b and state 12a and state 12b of the electronic device 101 may be determined depending on a relative position of a second case 220 with respect to a first case 210. The electronic device 101 may be changed (or switched) between state 11a and state 11b and state 12a and state 12b by a manipulation of a user or a mechanical operation (e.g., a motor).

In an embodiment, state 11a and state 11b of the electronic device 101 may mean that an area (or size) of an exposed area of a display assembly 360, which is exposed to (or defines) a front surface (e.g., a surface that faces the +z-axis direction) of the electronic device 101, is relatively contracted compared to state 12a and state 12b. State 12a and state 12b of the electronic device 101 may mean that an area size (or size) of an exposed area of a display assembly 360, which is exposed to (or defines) a front surface (e.g., a surface that faces the +z-axis direction) of the electronic device 101, is relatively expanded compared to state 11a and state 11b. For example, state 11a and state 11b may mean a state, in which an exposed area of a display assembly 360, which is visually exposed to a front surface of the electronic device 101, has a minimum size, and state 12a and state 12b may mean a state, in which an exposed area of a display assembly 360, which is exposed to the front surface of the electronic device 101, has a maximum size. Although not illustrated, the state of the electronic device 101 may further include at least one intermediate state (e.g., a partially expanded state or a partially open state) that is defined between state 11a and state 11b and state 12a and state 12b. For example, the at least one intermediate state may mean one or more states, in which a size of an exposed area of a display assembly 360 is greater than that of state 11a and state 11b and smaller than that of state 12a and state 12b.

In an embodiment, at a retracted position corresponding to state 11a and state 11b, the first case 210 and the second case 220 of the electronic device 101 may form a closed state. As an example, the first case 210 may include a first case lower end 210_sd3 (or a first lower end side part), a first case upper end 210_sd4 (or a first upper end side part), a first case right part 210_sd1 (or a first right side part), a first case left part 210_sd2 (or a first left side part), and a case bottom part. The second case 220 may include a second case upper end 220_fr (or a second upper end side part), a second case right part 220_sd1 (or a second right side part), and a second case left part 220_sd2 (or a second left side part). Additionally, a bottom part may be further disposed on a rear surface of the second case 220. As another example, the electronic device 101 may include a configuration, in which the first housing 410 and the second case 220 are integrated. In this case, the second case 220 may be integrated as a decorative member of the first housing 410. A rear cover 440 may be disposed on a rear surface of the electronic device 101. The rear cover 440 may include a first rear cover 441 that is disposed in a direction of a rear surface of the first case 210, and a second rear cover 442 that is disposed in a direction of a rear surface of the second case 220. As an example, the first rear cover 441 may be disposed below a bottom part of the first case 210. The second rear cover 442 may be disposed in a downward direction (e.g., the −z-axis direction) of the second case 220 (or below a bottom part of the second case 220). In state 11a and state 11b, the first case 210 and the second case 220 of the electronic device 101 may be disposed to be close to each other within a predefined distance. As an example, in state 11a and state 11b, a one-side end of a first case right part 210_sd1 and a one-side end of a second case right part 220_sd1 may contact each other or may be disposed to be close to each other within a specific distance (e.g., several μm to several mm). As an example, in state 11a and state 11b, a one-side end of a first case left part 210_sd2 and a one-side end of a second case left part 220_sd2 may contact each other or may be disposed to be close to each other within a specific distance. Alternatively, in state 12a and state 12b, one side (e.g., an end in the y-axis direction) of the first case 210 and one side (e.g., an end in the −y-axis direction) of the second case 220 may contact each other or may be spaced apart from each other with a predefined second gap (e.g., a gap having a length greater than that of the first gap or several mm to several cm or more).

In an embodiment, referring to state 12a and state 12b, the second case 220 may change a state of the electronic device 101 as the second case 220 is slid with respect to the first case 210. For example, the electronic device 101 may be changed from state 11a and state 11b to state 12a and state 12b as the second case 220 is moved in a first direction (or the y-axis direction) with respect to the first case 210. Conversely, the electronic device 101 may be changed from state 12a and state 12b to state 11a and state 11b as the second case 220 is moved in a second direction (or the −y-axis direction), which is opposite to the first direction, with respect to the first case 210.

In an embodiment, in the electronic device 101, a size of an exposed area of a display assembly 360 that is visually exposed to a front surface of the electronic device 101 may be changed in response to sliding of the second case 220. The display assembly 360 may be configured such that, in a state in which the display assembly 360 is supported by other components of the electronic device 101, at least a portion of the display assembly 360 is rotated and is moved linearly in response to sliding of the second case 220, so that an area exposed to a front surface of the electronic device 101 is expanded or contracted. The display assembly 360 may include an at least partially flexible part. For example, a display that is included in the display assembly 360 may be a flexible display.

In an embodiment, the display assembly 360 may include, at a retracted position illustrated in state 11a and state 11b, a first screen area 261 that defines a front surface, and a first extension area 263 and a second extension area 262 that extend from the first screen area 261 and are disposed in an interior of the first case 210. The first extension area 263 may be located between the first screen area 261 and the second extension area 262 at a retracted position, and may include an area that defines a curved surface. The second extension area 262 may include an area that is disposed to face a bottom surface of the first case 210 at a retracted position. The second extension area 262 may include a non-display area, in which pixels are not disposed in at least a portion thereof. Alternatively, an entirety of the second extension area 262 may include display areas.

In an embodiment, at a retracted position, at least a portion of the first extension area 263 may be covered by the first case upper end 210_sd4, and the second extension area 262 may be disposed between a lower portion of the second housing 420 and a bottom surface of the first case 210 (e.g., a first case bottom part). The display assembly 360 may include, at an extended position illustrated in state 12a and state 12b, a first screen area 261 that defines a front surface, and at least a portion of a first extension area 263 and a second extension area 262 that extend from the first screen area 261. At the extended position, the first extension area 263 may be disposed on the front surface together with the first screen area 261. Alternatively, at the extended position, the first screen area 261, the first extension area 263, and the second extension area 262 may define a front surface of the display assembly 360. The electronic device 101 may have a partially retracted position or a partially extended position corresponding to a position between the retracted position and the extended position. In this case, a portion of the second extension area 262 (or an area, in which pixels that may display a screen are disposed, and that is disposed in a rearward direction of the first screen area 261 at the retracted position) may be disposed on a front surface (e.g., one surface that may be observed from the outside), and another portion thereof may be disposed to face a curved area, in which the first extension area 263 is disposed at the retracted position, or a rearward direction (e.g., the −z-axis direction). Alternatively, at a partially retracted position, a portion of the second extension area 262 may be disposed on the front surface, and another portion thereof may be disposed in a curved area, in which the first extension area 263 is disposed at the retracted position. Alternatively, depending on a partial contraction degree (or a partial extension degree), a size of an area of the second extension area 262, which is disposed on the front side, may be different. As an example, in a state of the extended position, at which screen areas (e.g., the first screen area 261, the first extension area 263, and the second extension area 262) included in the display assembly 360 are disposed on the front surface, the first housing 410 may be partially exposed when a side surface of the electronic device 101 is observed, and the second housing 420 may be partially exposed when a rear surface of the electronic device 101 is observed.

As the first case 210 is slid with respect to the second case 220 (or the second case 220 is slid with respect to the first case 210), the second extension area 262 may be inserted into an interior of the first case 210 (e.g., a slide-in operation) or may be extracted to an outside of the first case 210 (e.g., a slide-out operation). In an embodiment disclosed in the disclosure, the first screen area 261, the first extension area 263, and the second extension area 262 of the display 260 are not areas that are physically distinguished, and it does not necessarily imply that their shapes or properties are distinct.

A structure of the electronic device 101 that will be described below corresponds to an example of an electronic device 101, of which a size of a screen display area may vary, and the electronic device 101, of which the screen display area varies, may be implemented by various methods, in addition to the structure disclosed in the disclosure. In the disclosure, the term “state” may be understood as referring to an operation of the electronic device 101 or a structural form, shape, or configuration of the display.

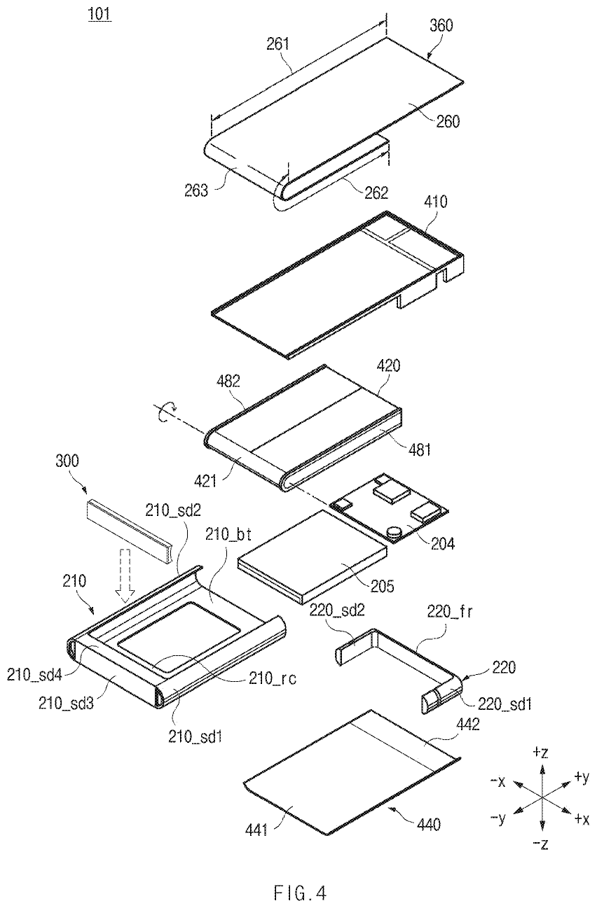

FIG. 4 is an exploded perspective view illustrating an electronic device according to an embodiment of the disclosure.

Referring to FIGS. 2 to 4, the electronic device 101 according to an embodiment may include a first case 210, a second case 220, a display assembly 360, a first housing 410, side members 481 and 482, a second housing 420, a first-type auxiliary structure 300 (or a structure, a first-type structure, a display support structure, or a structure for preventing damage and for waterproofing or dustproofing), and a rear cover 440 (or a back cover). For example, the electronic device 101 may be a foldable electronic device or a rollable electronic device.

According to an embodiment, the first case 210 may define at least a portion of an appearance of the electronic device 101. The first case 210 may provide a space, in which various electronic components are disposed. The second case 220 may be slidably connected to the first case 210. For example, the second case 220 may be moved in the +Y axis from the first case 210, or may be moved in the −Y axis to the first case 210. However, this is by way of example, and a direction, in which the second case 220 is moved, is not limited thereto. For example, the second case 220 may be configured to be extracted in the +X axis from the first case 210 or be moved in the −X axis to the first case 210 such that the display 260 is expanded in a widthwise direction (e.g., the X-axis direction) (e.g., a rightward or leftward direction) of the electronic device 101. In this case, the electronic device 101 may be changed such that a structure of the currently illustrated drawing is slid in the X-axis direction.

According to an embodiment, the first case 210, as described above, may include a first case lower end 210_sd3 (or a lower end side part), a first case upper end 210_sd4 (or an upper end side part), a first case right part 210_sd1, a first case left part 210_sd2, and a first case bottom part 210_bt. The first case upper end 210_sd4 may extend from an upper portion of the first case lower end 210_sd3 in the y-axis direction in parallel to the first case bottom part 210_bt. A length of the first case upper end 210_sd4 in the y-axis direction may be formed to be shorter than a length of the first case bottom part 210_bt in the y-axis direction. Lengths of the first case right part 210_sd1, the first case left part 210_sd2, and the first case bottom part 210_bt in the y-axis direction may be formed to be the same. A portion of the printed circuit board 204, the battery 205, the first housing 410, and the second housing 420 may be seated in the first case 210. A portion (e.g., the first rear cover 441) of the rear cover 440 may be disposed below the first case bottom part 210_bt. The first case 210 may define a case groove 210_rc that includes a first case lower end 210_sd3, a first case upper end 210_sd4, a portion of a first case right part 210_sd1, a portion of a first case left part 210_sd2, and a portion of a first case bottom part 210_bt. The first-type auxiliary structure 300 may be disposed in the case groove 210_rc. At least a portion of the display assembly 360 may be disposed in the case groove 210_rc. The first-type auxiliary structure 300 and a portion (e.g., the first extension area 263) of the display assembly 360 may be disposed in the case groove 210_rc to face each other.

According to an embodiment, the first-type auxiliary structure 300, in a state, in which the first-type auxiliary structure 300 is moved toward a bottom surface of the case groove 210_rc or moved in the y-axis direction, may in turn be moved in the −y-axis direction. As an example, the first-type auxiliary structure 300 may be fixed to an inner surface (e.g., a bottom surface of the first case lower end 210_sd3 observed in the y-axis direction or an opposite surface to the first case lower end 210_sd3 observed from the outside) of the first case lower end 210_sd3. In response to a control of the processor (e.g., the processor 120 of FIG. 1) of the electronic device 101, at least a portion of the first-type auxiliary structure 300 may be moved in the y-axis direction (or toward the first extension area 263).

According to an embodiment, the second case 220 may include a portion (e.g., the second case upper end 220_fr) that surrounds at least a portion of an upper end periphery (e.g., a −y-axis periphery) of the display assembly 360 or the first housing 410, a second case left part 220_sd2 that extends in the −y-axis direction from a one-side periphery (e.g., a left-side periphery) of the second case upper end 220_fr, and a second case right part 220_sd1 that extends in the −y-axis direction from an opposite-side periphery (e.g., a right-side periphery) of the second case upper end 220_fr. The above-described second case 220 may include a C shape, and may be fastened (or coupled) to the first housing 410 from the −y-axis direction to the y-axis direction. At least a portion (e.g., the first case left part 210_sd2 and the first case right part 210_sd1) of the first case 210 and at least a portion (e.g., the second case left part 220_sd2 and the second case right part 220_sd1) of the second case 220 may be disposed to face each other.

According to an embodiment, at least a portion of the first housing 410 may be located in an interior space of the electronic device 101, which is defined by the first case 210 and the second case 220. At least a portion of the first housing 410 may be coupled to the second case 220 or may be integrally formed with the second case 220. The second case 220 and the first housing 410 may define a first frame (or a first frame structure or a first framework) that may endure a load of a specific level or more to contribute to a durability or a rigidity of the electronic device 101. Electronic components or various members that are related to the electronic components may be disposed on the first frame or may be supported by the first frame. The first housing 410 may support at least a portion of the display assembly 360 in a rearward direction (e.g., the −Z direction). The first housing 410 may support at least a portion (e.g., the first screen area 261) of the display 260. The first housing 410 may be attached (or bonded) to at least a portion (e.g., the first screen area 261 of the display 260) of the display 260 through an adhesive member (not illustrated). The first housing 410 may linearly reciprocate in the +Y/−Y direction. The first housing 410 may be slid with respect to the first case 210 together with the second case 220.

According to an embodiment, the second housing 420 (or a fixing bracket, a fixing support structure, a fixing support member, a fixing frame, or a first plate) may be located in an interior space of the electronic device 101, which is defined by the first case 210. The second housing 420 may be connected to the first case 210. Alternatively, at least a portion of the second housing 420 may be integrally formed with the first case 210. The first case 210 and the second housing 420 may define a second frame (or a second frame structure or a second framework) that may endure a load of a specific level or more to contribute to a durability or a rigidity of the electronic device 101. Electronic components or various members that are related to the electronic components may be disposed on the second frame or may be supported by the second frame. As an example, a battery 205 and a printed circuit board 204 may be disposed on the second housing 420 or the second frame or may be supported by the second frame.

According to an embodiment, the second housing 420 may support at least a portion (e.g., the first extension area 263 and at least a portion of the second extension area 262) of the display 260. As an example, the second housing 420 may include a curved area 421, and may be disposed toward the first extension area 263 of the display 260 depending on the contracted or extended position of the electronic device 101. When the second case 220 is slid, the first extension area 263 and the second extension area 262 of the display 260 may be extracted from the interior space of the first case 210 or may be inserted into the interior space of the first case 210.

According to an embodiment, the side member 481 and 482 may guide a movement path of the display assembly 360 while the second case 220 is slid with respect to the first case 210. As an example, the side member 481 and 482 may be connected to the first case 210, and may not be slid when the second case 220 is slid with respect to the first case 210. As another example, the side member 481 and 482 may be connected to the second case 220, and may be slid with respect to the first case 210 together with the second case 220. At least one side member 481 and 482 may be provided. As an example, a pair of side members 481 and 482 may be provided, and may be located on opposite sides (e.g., the −X direction and the +X direction) of the first case 210. As an example, a first side member 481 that is located on the right side, among the side members 481 and 482, may be connected to one side portion (e.g., an end in the −X direction) of the first case 210, and a second side member 482 that is located on the left side, among the side members 481 and 482, may be connected to an opposite side portion (e.g., an end in the +X direction) of the first case 210. However, this is by way of example, and the positions and/or the number of the side members 481 and 482 are not limited thereto.

According to an embodiment, at least a portion of the display assembly 360 may be supported by at least any one of the first case 210, the second case 220, the first housing 410, or the second housing 420. As an example, a portion of the display assembly 360 may be supported by the first housing 410, and another portion thereof may be supported by the second housing 420. A display area of the display assembly 360 may be changed as the second case 220 is relatively moved with respect to the first case 210 (or the first housing 410 is relatively moved with respect to the second housing 420). As an example, when the first housing 410 is extracted from the second housing 420, an area of the display 260 of the display assembly 360 may be visually exposed more, and an area that displays a screen of the display 260 may be expanded to the first screen area 261, the first extension area 263, and the second extension area 262. When the first housing 410 is inserted into the second housing 420, an area of the display 260 of the display assembly 360, which is visually exposed, may be reduced, and an area that displays the screen of the display 260 may be reduced to the first screen area 261. The display assembly 360 may include a display, a support sheet, and a multi-bar assembly (or a multi-joint hinge structure or a support structure). However, this is by way of example, and a configuration of the display assembly 360 is not limited thereto. As an example, the display assembly 360 may include various layers, such as a cover layer and/or a touch panel.

According to an embodiment, the display 260 may visually display information. The display 260 may be formed such that at least a portion thereof is flexible. A display area of the display 260, which is visually exposed to the outside, may be changed as the second case 220 is relatively moved with respect to the first case 210 (or as the first housing 410 is relatively moved with respect to the second housing 420). Hereinafter, for convenience of description, with respect to the display 260, a direction, in which information is visually displayed by the display 260, will be referred to as a forward direction (e.g., the +Z direction), and a direction opposite to the forward direction will be referred to as a rearward (or backward) direction (e.g., the −Z direction).

According to an embodiment, the rear cover 440 may be disposed on or coupled to rear surfaces of the first case 210 and the second case 220 to define at least a portion of an appearance of the electronic device 101. As an example, the rear cover 440 may include a first rear cover 441 that is coupled to a first case bottom part 210_bt of the first case 210, and a second rear cover 442 that is coupled to a rear surface of the second case 220. The rear cover 440 may provide a decorative effect in an appearance of the electronic device 101.

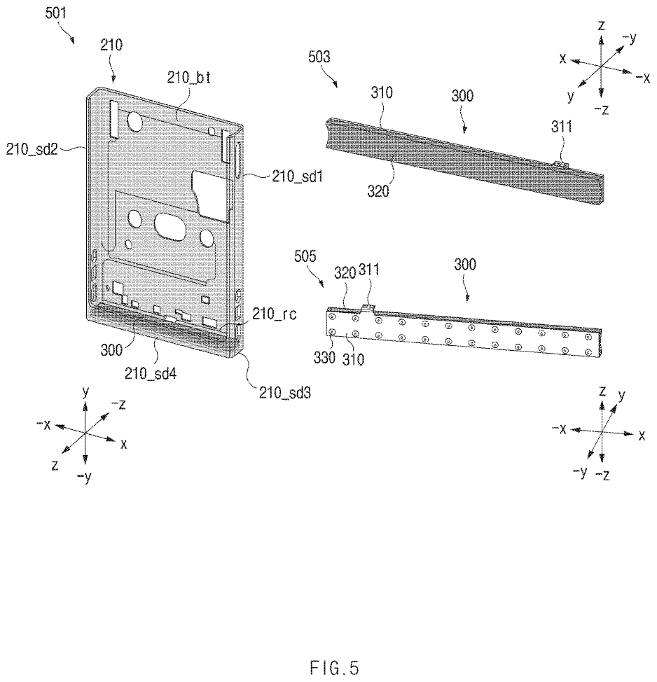

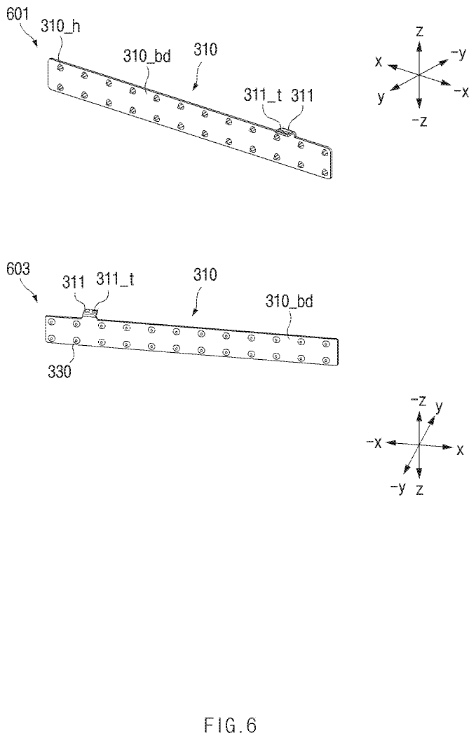

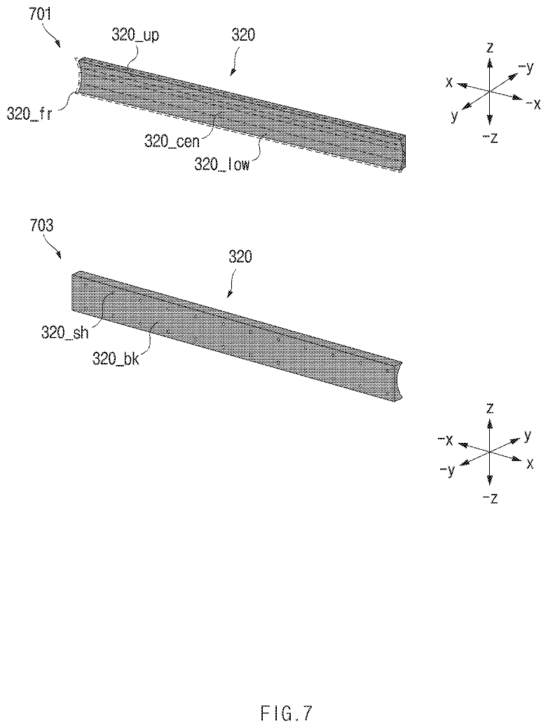

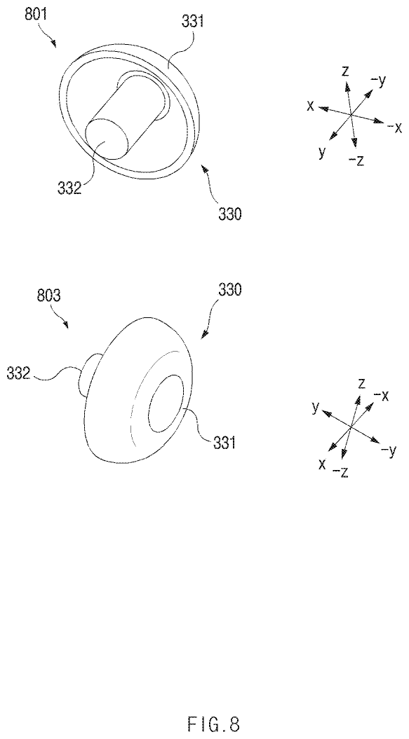

FIG. 5 is a view illustrating an example of a first case and a first-type auxiliary structure according to an embodiment of the disclosure. FIG. 6 is a view illustrating an example of a structure substrate of a first-type auxiliary structure according to an embodiment of the disclosure. FIG. 7 is a view illustrating an example of a support structure of a first-type auxiliary structure according to an embodiment of the disclosure. FIG. 8 is a view illustrating an example of an actuator of a first-type auxiliary structure according to an embodiment of the disclosure.

In FIG. 5, state 501 corresponds to a view illustrating an example of an appearance of the first case 210, to which a first-type auxiliary structure 300 is coupled, state 503 corresponds to a view illustrating an example of an appearance of the first-type auxiliary structure 300 in the first direction, and state 505 corresponds to a view illustrating an example of an appearance of the first-type auxiliary structure 300 in the second direction. In FIG. 6, state 601 corresponds to a view illustrating an example of an appearance of the structure substrate 310 in the first direction, and state 603 corresponds to a view illustrating an example of an appearance of the structure substrate 310 in the second direction. In FIG. 7, state 701 corresponds to a view illustrating an example of an appearance of the support structure 320 in the first direction, and state 703 corresponds to a view illustrating an example of an appearance of the support structure 320 in the second direction. In FIG. 8, state 801 corresponds to a view illustrating an example of an appearance of any one actuator 330, among the plurality of actuators, in the first direction, and state 803 corresponds to a view illustrating an example of an appearance of any one actuator 330, among the plurality of actuators, in the second direction.

Referring to FIGS. 2 to 5, as described above, the first case 210 may include a first case lower end 210_sd3, a first case upper end 210_sd4, a first case right part 210_sd1, a first case left part 210_sd2, and a first case bottom part 210_bt. The first case bottom part 210_bt may have, for example, a surface having a size similar to or identical to a size of a bottom surface of the second housing 420 described above. Alternatively, the first case bottom part 210_bt may have a size corresponding to a size of the first rear cover 441. The first case bottom part 210_bt may include at least one hole that passes through the first case bottom part 210_bt in forward and rearward directions (e.g., the Z-axis direction and the −Z-axis direction). A first case right part 210_sd1 that extends while having a height (e.g., a height corresponding to a thickness of the electronic device 101) that is predefined at an angle (or a direction that is perpendicular to a bottom surface of the first case bottom part 210_bt or the z-axis direction) from the bottom surface of the first case bottom part 210_bt may be disposed at a right-side periphery of the first case bottom part 210_bt. A first case left part 210_sd2 that extends while having a height (e.g., a height corresponding to a thickness of the electronic device 101) that is predefined at an angle (or a direction that is perpendicular to a bottom surface of the first case bottom part 210_bt or the z-axis direction) from the bottom surface of the first case bottom part 210_bt may be disposed at a left-side periphery of the first case bottom part 210_bt. A first case lower end 210_sd3 that extends while having a height (e.g., a height corresponding to a thickness of the electronic device 101) that is predefined at an angle (or a direction that is perpendicular to a bottom surface of the first case bottom part 210_bt or the z-axis direction) from the bottom surface of the first case bottom part 210_bt may be disposed at a lower end periphery of the first case bottom part 210_bt. Peripheries of the first case lower end 210_sd3 on opposite sides may be connected to an upper end on one side of the first case left part 210_sd2 and an upper end on one side of the first case right part 210_sd1. The first case upper end 210_sd4 may be disposed to extend from an upper periphery (e.g., a periphery in the Z-axis direction) of the first case lower end 210_sd3 toward the y-axis direction. Correspondingly, a lower periphery of the first case upper end 210_sd4 may be connected to an upper periphery of the first case lower end 210_sd3, and peripheries of opposite sides of the first case upper end 210_sd4 may be connected to one side of the first case left part 210_sd2 and one side of the first case right part 210_sd1. According to an embodiment, a lower periphery (e.g., a periphery in the −Y-axis direction) of the first case 210 may be closed by the first case lower end 210_sd3. Alternatively, a case groove 210_rc (or a groove or a structure arrangement recess) that is formed by the first case lower end 210_sd3, the first case upper end 210_sd4, a portion of the first case left part 210_sd2, and a portion of the first case right part 210_sd1 may be disposed (formed) at a lower periphery of the first case 210. The first-type auxiliary structure 300 may be disposed in (or fixed to) the case groove 210_rc. According to an embodiment, a y-axis length of the first case upper end 210_sd4 may be formed to be different from a y-axis length of at least one of the first case right part 210_sd1 or the second case left part 220_sd2. For example, a y-axis length of the first case upper end 210_sd4 may be less than a y-axis length of the first case right part 210_sd1. Alternatively, a y-axis length of the first case upper end 210_sd4 may be formed to be smaller than or similar to a height of the first case lower end 210_sd3.

Referring to state 503 and state 505 of FIGS. 2 to 5, and at least a portion of FIG. 6, the first-type auxiliary structure 300 may include a structure substrate 310 (or a substrate), a support structure 320 (or a protective structure), and a plurality of actuators 330.

The structure substrate 310 may include a base substrate 310_bd that is formed such that a length in the x-axis direction is longer than a z-axis or y-axis length. As an example, a one-side length (e.g., a length in the x-axis direction) of the base substrate 310_bd may have a size that is similar to or the same as (or smaller than) a one-side length (e.g., a length in the x-axis direction) of the case groove 210_rc of the first case 210. The base substrate 310_bd may be fixed to a bottom surface of the case groove 210_rc. The base substrate 310_bd may include a plurality of holes 310_h, in which at least some of the plurality of actuators 330 may be disposed. The plurality of holes 310_h may be formed to pass through front and rear surfaces (e.g., surfaces in the y-axis and −y-axis directions) of the base substrate 310_bd. The plurality of holes 310_h may be formed regularly, for example, according to a specific pattern. As an example, the base substrate 310_bd may include a plurality of holes 310_h corresponding to the number of the plurality of actuators 330.

According to an embodiment, the structure substrate 310 may be formed such that a plurality of layers overlap each other. As an example, a wire that may supply power to the plurality of actuators 330 may be disposed on at least one of the plurality of layers of the structure substrate 310. For example, the structure substrate 310 may include a wire layer, support layers that are disposed on front and rear surfaces of the wire layer, and at least one adhesive layer that is used for adhesion to a bottom surface of the case groove 210_rc. Alternatively, the structure substrate 310 may be configured as a single layer in which a groove for the wire is formed. As an example, at least one of the plurality of layers of the structure substrate 310 may include a board connection portion 311 that may be electrically connected to a printed circuit board 204 (or a first printed circuit board 1300 to be described later) of the electronic device 101 The board connection portion 311 may be disposed to protrude from one side of the base substrate 310_bd. For example, the board connection portion 311 may be disposed to protrude from a point of the base substrate 310_bd in the y-axis direction. The board connection portion 311 may be disposed (disposed to protrude) toward a rearward direction (e.g., a surface observed in the −Z-axis direction) of the first case bottom part 210_bt through a through-hole formed in the first case bottom part 210_bt. At least one terminal 311_t (or an electrode) may be disposed on the board connection portion 311. The terminal 311_t may be electrically connected to wires formed in the base substrate 310_bd of the structure substrate 310, and may be used to supply power to the plurality of actuators 330 through the printed circuit board 204 (or the first printed circuit board 1300 to be described later).

According to an embodiment, the structure substrate 310 may be formed of a material having a higher rigidity than that of the support structure 320. For example, at least a portion of the structure substrate 310 may be formed of a metal material. Alternatively, at least a portion of the structure substrate 310 may be formed of a reinforced plastic or a polymer that may provide a rigidity equal to or greater than a specific level (e.g., polyethylene terephthalate (PET), polymethyl methacrylate (PMMA)). Alternatively, when the structure substrate 310 includes a plurality of layers, the plurality of layers may be formed of different materials. For example, one layer that faces a bottom surface of the case groove 210_rc, among the plurality of layers of the structure substrate 310, may include an adhesive layer. The adhesive layer may bond an area of one surface of the structure substrate 310, in which the plurality of actuators 330 are not formed, and a bottom surface of the case groove 210_rc.

Referring to FIGS. 2 to 6, and FIG. 7, the support structure 320 may be disposed in a direction (or on a first surface) of the first surface (e.g., a surface that faces the y-axis direction) of the structure substrate 310. The support structure 320 and the structure substrate 310 may be spaced apart from each other. Alternatively, an air gap may be formed between the support structure 320 and the structure substrate 310. The support structure 320 may be moved in the y-axis direction or in the −y-axis direction from the structure substrate 310 in response to operations of the plurality of actuators 330. As an example, the support structure 320 may be moved from the structure substrate 310 in the y-axis direction in a state (e.g., a state of the retracted position or the extended position), in which screen areas of the electronic device 101 are fixed, to be in contact with one area (e.g., the first extension area 263 of the display 260 at the retracted position or the second extension area 262 of the display 260 at the extended position) of the display assembly 360 (or to be close to the one area by less than a predefined first distance). In this regard, at least a portion of a rear surface 320_bk of the support structure 320, which faces the structure substrate 310, may be formed to be flat (or an entirety thereof is flat), and at least a portion of a front surface 320_fr of the support structure 320, which faces the display assembly 360, may be formed to be curved (or an entirety thereof is formed to be concave). Support recesses 320_sh that are fastened to the plurality of actuators 330 may be disposed on the rear surface 320_bk of the support structure 320. The support recesses 320_sh may include a number corresponding to a number of the plurality of actuators 330.

According to an embodiment, the support structure 320 may be formed of a material having a rigidity that is lower than that of the structure substrate 310 (or having a ductility that is higher (or greater) or an elasticity that is greater). For example, at least a portion of the support structure 320 may be formed of at least one of rubber, silicone, fiber (e.g., microfiber, quilt, fleece, cotton, flannel, velvet, veil), a sponge structure, corduroy, or a polymer material. As an example, the support structure 320 may include a plurality of layers. Correspondingly, at least some of the plurality of layers of the support structure 320 may be formed of different materials. For example, a first layer of the support structure 320, which faces the structure substrate 310, may be formed of a material (e.g., plastic, reinforced plastic, a plastic alloy, or a polymer material having a rigidity equal to or greater than a specific level) having a relatively higher rigidity than that of other layers of the support structure 320. A second layer of the support structure 320, which is positioned on the first layer of the support structure 320, may be formed of a soft material (e.g., rubber, silicone, fleece, or a polymer material having a ductility that is lower (or smaller) than that of the first layer) that may prevent damage to the display assembly 360 when the support structure 320 contacts the display assembly 360 due to an external impact. Alternatively, the support structure 320 may be formed of different materials partially (or for a position thereof).

As an example, the support structure 320 may include a central area 320_cen, a structure upper area 320_up, and a structure lower area 320_low. The structure upper area 320_up and the structure lower area 320_low may include areas that protrude further than the central area 320_cen in the y-axis direction with respect to a rear surface 320_bk of the support structure 320. Alternatively, the structure upper area 320_up and the structure lower area 320_low may include peripheral areas in the z-axis direction or the −z-axis direction with respect to the central area 320_cen. At least a portion of the structure upper area 320_up may include an area of the support structure 320, which is disposed to be close to the first case upper end 210_sd4. At least a portion of the structure lower area 320_low may include an area of the support structure 320, which is disposed to be close to the first case bottom part 210_bt.

According to an embodiment, one area (e.g., the central area 320_cen) (e.g., a concave center line in the x-axis direction) of a concave portion of the support structure 320 may be formed of a first material (e.g., rubber or silicone), and at least some of upper and lower peripheral areas (e.g., the structure upper area 320_up and the structure lower area 320_low) with respect to the central area 320_cen may be formed of a second material (e.g., wool or fiber) that is different from the first material. Alternatively, at least a portion of the central area 320_cen and the structure lower area 320_low of the support structure 320 may be formed of a first material (e.g., a material that may achieve a purpose of impact absorption, such as rubber or silicone), and at least a portion of the structure upper area 320_up may be formed of a second material (e.g., a material that may satisfy a purpose of waterproofing or dustproofing, such as wool or a fiber material) that is different from the first material. As another example, the central area 320_cen, the structure lower area 320_low, and the structure upper area 320_up may be formed of materials that are different from each other.

Referring to FIGS. 2 to 8, at least some of the plurality of actuators 330 may be disposed in a plurality of holes 310_h formed in the structure substrate 310 (e.g., the base substrate 310_bd). Each of the plurality of actuators 330 may have a state in which power is not supplied (or a power-off state), and a state in which power is supplied (or a power-on state). When power is supplied (or when power is not supplied), each of the plurality of actuators 330 may move forward at least a portion of the support structure 320 in a first surface direction (e.g., the y-axis direction or a direction that faces the display assembly 360) of the structure substrate 310. When power is cut off (or when power in an opposite direction is supplied, or when the cut-off power is supplied), each of the plurality of actuators 330 may move rearward at least a portion of the support structure 320 in a second surface direction (e.g., the −y-axis direction or a direction that faces a bottom surface of the case groove 210_rc) of the structure substrate 310. As an example, the plurality of actuators 330 may move the support structure 320 toward the display assembly 360, or may space the support structure 320 apart from the display assembly 360.

According to an embodiment, the actuator 330 may include a base portion 331 and a pillar portion 332, as illustrated in FIG. 8. At least a portion of the base portion 331 may have a specific thickness and may include a hemispherical shape in which a space is formed at a central portion thereof. Alternatively, the base portion 331 may include an umbrella shape that is rounded about a ceiling while an inner side of the ceiling or an outer side of the ceiling is partially formed to be flat. The base portion 331 may be deformed such that a protruding direction of the ceiling becomes opposite when power is supplied from the outside (or when power supply is cut off). A pillar portion 332 may be disposed at an inner center of the base portion 331. As an example, the pillar portion 332 may include a cylindrical shape in which a cross-section at one side is circular. One end of the pillar portion 332 may be fixed (or adhered) to an inner side of the ceiling of the base portion 331. The pillar portion 332 may be disposed perpendicular to a center of the ceiling of the base portion 331. A length of the pillar portion 332 in the y-axis direction may be formed to be greater than a thickness of the base portion 331 in the y-axis direction. Accordingly, the plurality of actuators 330 may pass through a plurality of holes 310_h formed in the base substrate 310_bd of the structure substrate 310 to be coupled (or adhered) to a rear surface 320_bk (or the support recesses 320_sh) of the support structure 320. The pillar portion 332 may maintain a shape or form regardless of power supply.

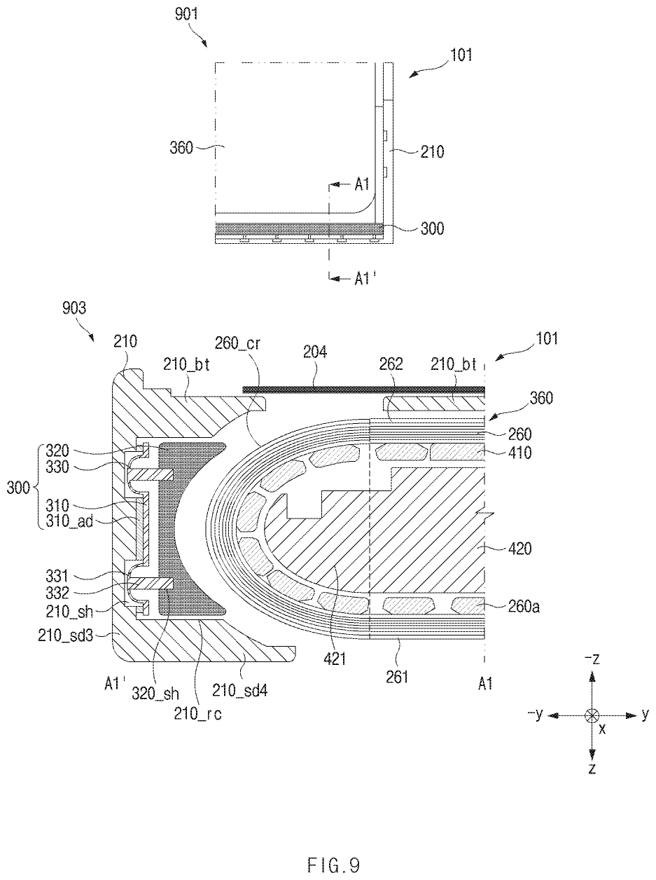

FIG. 9 is a view illustrating a first arrangement state of an electronic device according to an embodiment of the disclosure. As an example, a state 901 of FIG. 9 is a diagram illustrating a portion of a front surface of the electronic device 101 when the electronic device 101 is in a first arrangement state, and a state 903 of FIG. 9 is a diagram illustrating an example of a cross section of a portion of the electronic device 101 in state 901, which is taken along cutting line A1-A1′.

Referring to FIGS. 2 to 9 and state 901 and state 903 of FIG. 9, the electronic device 101 may include, as an example, a first housing 410, a second housing 420, a display assembly 360, a first case 210, and a first-type auxiliary structure 300. Additionally or alternatively, the electronic device 101 may further include at least some of the components described above with reference to FIG. 4.

According to an embodiment, a first arrangement state of the first-type auxiliary structure 300 may include a state in which the electronic device 101 is changed from a retracted position to an extended position, or a state in which the electronic device 101 is changed from an extended position to a retracted position. A user may instruct a position change by using at least one input means that is provided in the electronic device 101. The at least one input means may include at least one of at least one button that is disposed in the electronic device 101, a virtual key that is output through a screen user interface of the display 260 and that may instruct contraction or transformation to an extended position, at least one sensor that may sense a gesture corresponding to contraction or transformation to an extended position, and a microphone that may receive, by voice, contraction or transformation to an extended position.

According to an embodiment, the first case 210 may include a first case lower end 210_sd3, a first case upper end 210_sd4, and a first case bottom part 210_bt. Additionally or alternatively, the first case 210 may further include a first case right part 210_sd1 and a first case left part 210_sd2. According to an embodiment, a printed circuit board 204 (or at least one of the printed circuit board 204 and a first rear cover 441) may be disposed below the first case bottom part 210_bt. The first case lower end 210_sd3, the first case upper end 210_sd4, and the first case bottom part 210_bt may define a case groove 210_rc. Alternatively, the first case lower end 210_sd3, the first case upper end 210_sd4, the first case bottom part 210_bt, a portion of the first case right part 210_sd1, and a portion of the first case left part 210_sd2 may define the case groove 210_rc. At least a portion of the first-type auxiliary structure 300 may be disposed (or fixed) in the case groove 210_rc. In this regard, a structure arrangement recess 210_sh, in which at least a portion of the first-type auxiliary structure 300 is seated, may be formed on an inner surface of the case groove 210_rc (or an inner surface of the first case lower end 210_sd3). The structure arrangement recess 210_sh may be formed such that at least a portion thereof is recessed in the −y-axis direction from an inner surface (or a bottom of an inner surface of the first case lower end 210_sd3) of the case groove 210_rc. The structure arrangement recess 210_sh may include a shape corresponding to a rear surface (or at least a portion of a rear surface of the structure substrate 310, in which base portions 331 of the plurality of actuators 330 are disposed in a specific pattern) of the first-type auxiliary structure 300. As an example, at least a portion of the structure arrangement recess 210_sh may include grooves in which the base portions 331 of the plurality of actuators 330 are disposed. As an example, at least a portion of the structure arrangement recess 210_sh may include a number of grooves corresponding to a number of the plurality of actuators 330.

The first-type auxiliary structure 300 may include, as described above, a structure substrate 310, a support structure 320, and a plurality of actuators 330. At least a portion of the structure substrate 310 may be fixed or adhered to an inner surface of the first case lower end 210_sd3. In this regard, the electronic device 101 may further include an adhesive layer 310_ad between an inner surface of the first case lower end 210_sd3 and one surface (e.g., a surface that faces the −y-axis direction) of the structure substrate 310. As another example, the adhesive layer 310_ad may be included in the first-type auxiliary structure 300. At least some of the plurality of actuators 330 may be disposed in a plurality of holes (e.g., 310_h of FIG. 6) formed to pass through front and rear surfaces of the structure substrate 310. As an example, when the first-type auxiliary structure 300 is in a first arrangement state, the base portion 331 may be disposed (or formed) to be convex toward a rear surface (e.g., a surface observed from the −y-axis direction) of the structure substrate 310, a portion of the pillar portion 332 is located in a plurality of holes (310_h of FIG. 6), and a remaining portion of the pillar portion 332 may be disposed to protrude from a front surface (e.g., a surface observed from the y-axis direction or a surface that faces a direction, in which the support structure 320 is disposed) of the structure substrate 310. As an example, a remaining portion of the pillar portion 332 may be inserted into and fixed to the support recesses 320_sh formed in the support structure 320.

According to an embodiment, the support structure 320 may include a shape that is concave in the −y-axis direction. In this regard, at least a portion of the support structure 320 may include a curved surface. As an example, a curvature of the curved surface (e.g., a surface that faces the display assembly 360) of the support structure 320 may be formed to be the same as or similar to a curvature (or a curvature of a display curved area) of the display assembly 360. Alternatively, a curvature of a curved surface of the support structure 320 may be formed to be the same as or similar within a specific error range to a curvature of a curved area 421 of the second housing 420. Alternatively, a curvature of a curved surface of the support structure 320 may be the same as or similar to a curvature of the first extension area 263 in a retracted position state.

According to an embodiment, the display assembly 360 may include a display 260 and a multi-bar assembly 260a. The display 260 may include a first screen area 261, a first extension area 263, and a second extension area 262. The display curved area 260_cr may include, as an example, at least a portion of the first extension area 263 and the second extension area 262. As an example, the display curved area 260_cr may include the first extension area 263 in a state immediately before being changed from a retracted position to an extended position (or in a retracted position state). When at least a portion of the first extension area 263 is moved to a front surface (e.g., the z-axis direction) after a retracted position, the display curved area 260_cr may include a portion of the first extension area 263 and at least a portion of the second extension area 262. Alternatively, in a state in which an extended position is completed, the display curved area 260_cr may include at least a portion of the second extension area 262. The multi-bar assembly 260a may include a plurality of multi-bars, a support member that supports the plurality of multi-bars, and an adhesive layer that is disposed between the support member and the plurality of multi-bars.

According to an embodiment, in a first arrangement state in which a retracted position is changed to an extended position (or an extended position is changed to a retracted position), a gap having a predefined first size may be formed between the support structure 320 and the display curved area 260_cr. Because the gap having the predefined first size provides a non-contact state between a portion of the display assembly 360 (e.g., a portion of the display assembly 360 that is located on the curved area 421 of the second housing 420) and the first-type auxiliary structure 300, it is possible to prevent (or reduce) damage or deformation of the display assembly 360 (or the display 260) due to the first-type auxiliary structure 300. Additionally or alternatively, the first-type auxiliary structure 300 may prevent foreign substances from being introduced into the case groove 210_rc.

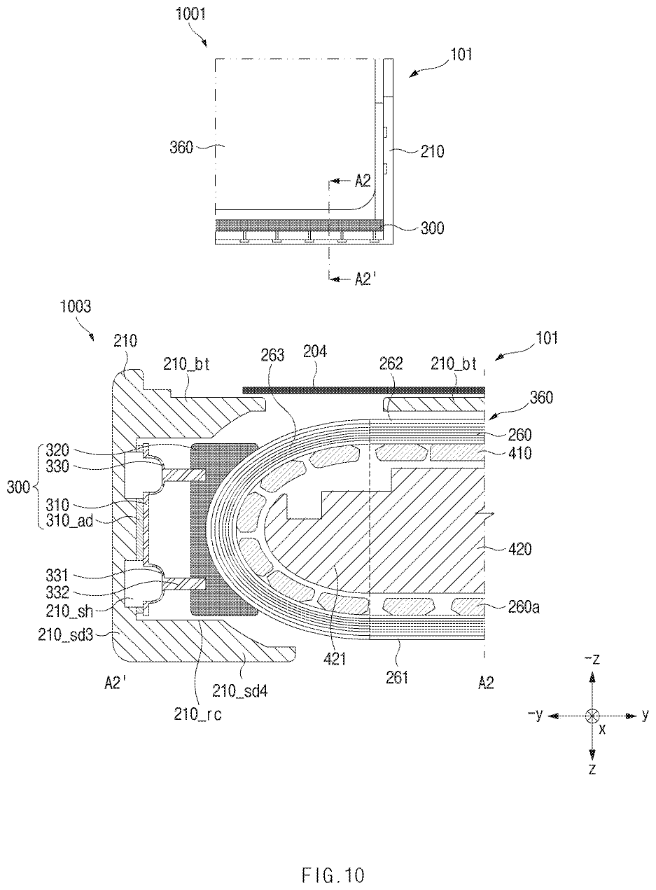

FIG. 10 is a view illustrating a second arrangement state of an electronic device according to an embodiment of the disclosure. As an example, a state 1001 of FIG. 10 is a diagram illustrating a portion of a front surface of the electronic device 101 when the electronic device 101 is in a second arrangement state, and a state 1003 of FIG. 10 is a diagram illustrating an example of a cross section of a portion of the electronic device 101 in state 1001, which is taken along cutting line A2-A2′.

Referring to FIGS. 2 to 10 and state 1001 and state 1003 of FIG. 10, the electronic device 101 may include, as an example, a first housing 410, a second housing 420, a display assembly 360, a first case 210, and a first-type auxiliary structure 300. Additionally or alternatively, the electronic device 101 may further include at least some of the components described above with reference to FIG. 4. As an example, the first-type auxiliary structure 300 may include a structure substrate 310, a support structure 320, and a plurality of actuators 330, and may further include an adhesive layer 310_ad that is disposed between the structure substrate 310 and at least a portion of an inner side of the case groove 210_rc. The case groove 210_rc of the first case 210 may include a structure arrangement recess 210_sh in which at least a portion of the first-type auxiliary structure 300 is disposed. The structure arrangement recess 210_sh may be configured (or formed) such that at least a portion of the base portions 331 of the plurality of actuators 330 may be disposed therein.

According to an embodiment, in a second arrangement state of the first-type auxiliary structure 300, the electronic device 101 may include a retracted position or an extended position state. Alternatively, according to an embodiment, the second arrangement state of FIG. 10 may include an intermediate state in which the display assembly 360 is temporarily fixed. The illustrated drawing is a view illustrating an example of a retracted position state. In an extended position, the second extension area 262 may be partially disposed in the display curved area 260_cr described above with reference to FIG. 9, or at least a portion of the first extension area 263 and the second extension area 262 may be disposed to face a front surface (the z-axis direction) together with the first screen area 261.

In the second arrangement state, the base portions 331 of the plurality of actuators 330 may protrude in the y-axis direction by supplied power (or by power supply being cut off). Alternatively, the base portions 331 of the plurality of actuators 330 may be disposed (or formed or deformed) to be convex in the y-axis direction. Correspondingly, the pillar portion 332 that protrudes in the y-axis direction from a center of the base portion 331 may be disposed to protrude further in the y-axis direction than in a previous state. As the pillar portion 332 is moved, the support structure 320 connected to the pillar portion 332 may be moved in the y-axis direction with respect to the structure substrate 310. As an example, a position of the support structure 320 may be changed in the case groove 210_rc. As an example, a gap having a second size that is smaller than the previously formed gap having the first size may be formed between one surface (e.g., a surface that faces the y-axis direction) of the support structure 320 and a portion (e.g., the first extension area 263) of the display assembly 360. Alternatively, one surface (e.g., a surface that faces the y-axis direction) of the support structure 320 and a portion of the display assembly 360 may be formed to be in contact with each other. According to an embodiment, in consideration of a portion in which a retracted position or an extended position state is maintained longer than a changing state (e.g., a state in which a retracted position is changed to an extended position or an extended position is changed to a retracted position), the plurality of actuators 330 may maintain the second arrangement state described in FIG. 10 when power is not supplied, and may maintain the first arrangement state described in FIG. 9 when power is supplied. However, the disclosure is not limited thereto, and may be configured in an opposite manner.

Because the support structure 320 of the first-type auxiliary structure 300 maintains a state in contact with a portion of the display assembly 360, it is possible to prevent damage to the portion of the display assembly 360 when an external impact is applied. Furthermore, while the support structure 320 of the first-type auxiliary structure 300 maintains a state in contact with a portion of the display assembly 360, it is possible to prevent foreign substances from being introduced through a gap between the first case upper end 210_sd4 and the display assembly 360, by blocking a space (or a gap) between the first case upper end 210_sd4 and the display assembly 360.

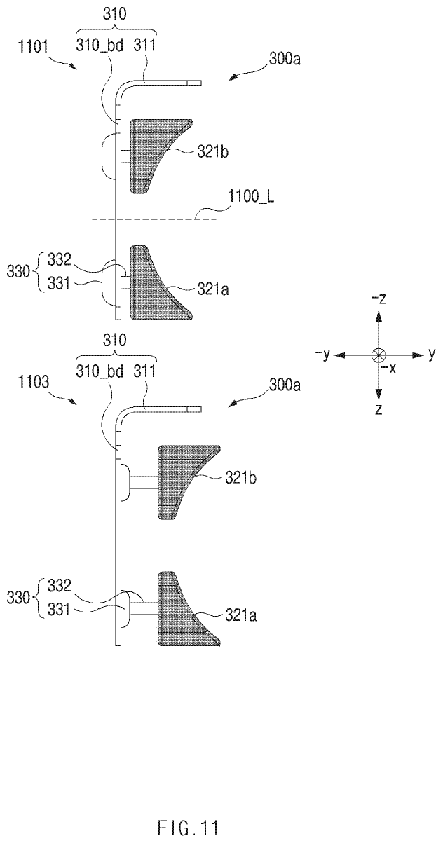

FIG. 11 is a view illustrating an example of a second-type auxiliary structure according to an embodiment of the disclosure. In FIG. 11, state 1101 is a view illustrating a modified form of a second-type auxiliary structure 300a (or a structure, a second-type structure) in a first arrangement state, and state 1103 is a view illustrating a modified form of the second-type auxiliary structure 300a in a second arrangement state.

Referring to FIGS. 2 to 11, the second-type auxiliary structure 300a may include a structure substrate 310, a first support structure 321a, a second support structure 321b, and a plurality of actuators 330. The structure substrate 310 may have the same structure as the structure substrate 310 described above with reference to FIGS. 4 to 10. As an example, the structure substrate 310 may include a base substrate 310_bd and a board connection portion 311. A wire that is connected to the plurality of actuators 330 may be disposed in the base substrate 310_bd, and at least one terminal may be disposed in the board connection portion 311. A plurality of holes (e.g., holes 310_h of FIG. 6), in which at least some of the plurality of actuators 330 are disposed, may be formed in the base substrate 310_bd.

The first support structure 321a may include a flat first surface (e.g., a surface that faces one surface (e.g., a surface that faces the y-axis direction) of the structure substrate 310) and a second surface (e.g., a surface opposite to the first surface) that has a specific inclination or is partially curved. At least one first support recess (e.g., the support recess 320_sh described above with reference to FIG. 9), into which the pillar portion 332 of the actuator 330 is inserted, may be formed at at least a portion of the first surface of the first support structure 321a. The first support structure 321a may include a structure of a shape, of which a width of a z-axis cross section increases from the −z-axis direction toward the z-axis direction. As an example, a width of a periphery in the z-axis direction among widths of a z-axis cross section of the first support structure 321a may be greater than a width of a periphery in the −z-axis direction. An inclination or a degree of curvature (or a curvature) of the second surface of the first support structure 321a may correspond to an inclination or a curvature of a partially curved surface (e.g., a curved surface that faces the z-axis direction or a diagonal direction) of a display curved area (e.g., the display curved area 260_cr of FIG. 9) of the display assembly 360.

The second support structure 321b may be disposed to be spaced apart from the first support structure 321a by a specific interval in an upward/downward direction (or the z-axis direction, or the −z-axis direction). A shape, a size, and a position of the second support structure 321b may have at least one of a shape, a size, and a position that are symmetric with respect to the first support structure 321a, based on an imaginary transverse center line (e.g., an imaginary transverse center line 1100_L that is parallel to the −x-axis or the x-axis and that crosses between the first support structure 321a and the second support structure 321b) of the structure substrate 310. As an example, the second support structure 321b may include one surface that faces the structure substrate 310 and is formed to be flat, and another surface that faces the display assembly 360 when mounted in the electronic device 101 and that has a specific inclination or a specific curvature (e.g., a curvature that is the same as or similar to a curvature of a portion of the display curved area 260_cr of FIG. 9). At least one second support recess (e.g., the support recess 320_sh described above with reference to FIG. 9), into which the pillar portion 332 of the actuator 330 is inserted, may be formed on one surface of the second support structure 321b.

The plurality of actuators 330 may include a first actuator group that is disposed in a first row (e.g., a row that is formed to be biased in the z-axis direction with respect to a transverse center line 1100_L of the structure substrate 310 and in which a plurality of actuators are arranged in the x-axis direction) and that is coupled to the first support structures 321a, and a second actuator group that is disposed in a second row (e.g., a row that is arranged parallel to the first row, is formed to be biased in the −z-axis direction with respect to the transverse center line 1100_L of the structure substrate 310, and in which a plurality of actuators are arranged in the x-axis direction) and that is coupled to the second support structures 321b. In a first arrangement state, the base portions 331 of the plurality of actuators 330 may be disposed in the −y-axis direction (or a first surface direction of the structure substrate 310 that faces a bottom surface of the case groove 210_rc) with respect to the structure substrate 310. Some of the pillar portions 332 of the plurality of actuators 330 may be located in the −y-axis direction with respect to the structure substrate 310, some of the pillar portions 332 may be located in holes formed in the structure substrate 310, and remaining some of the pillar portions 332 may be located in the y-axis direction with respect to the structure substrate 310. Correspondingly, a gap having a first size may be formed between the structure substrate 310 and the first support structure 321a (or between the structure substrate 310 and the second support structure 321b). In the second arrangement state, the base portions 331 of the plurality of actuators 330 may be disposed in the y-axis direction (or a direction that faces the display assembly 360) with respect to the structure substrate 310. The pillar portions 332 of the plurality of actuators 330 may be located in the y-axis direction with respect to the structure substrate 310. Correspondingly, a gap having a second size that is greater than the first size may be formed between the structure substrate 310 and the first support structure 321a (or between the structure substrate 310 and the second support structure 321b). According to an embodiment, when the second-type auxiliary structure 300a is mounted in the electronic device 101, at least a portion of the first support structure 321a and the second support structure 321b may be in contact with one surface of the display assembly 360 in the second arrangement state.

Meanwhile, in FIG. 11, a form in which two first support structures 321a and a second support structure 321b are disposed on the structure substrate 310 is illustrated, but the disclosure is not limited thereto. As an example, the electronic device 101 may include an auxiliary structure in which a plurality of first support structures 321a are disposed in a first row of the structure substrate 310 at specific intervals in the −x-axis direction or the x-axis direction, and a plurality of second support structures 321b are disposed in a second row at specific intervals. Alternatively, the electronic device 101 may include an auxiliary structure in which a first modified support structure that has a same shape as the first support structure 321a, of which a shape of a z-axis cross section is illustrated, and that has a length corresponding to a length of the structure substrate 310 in the x-axis direction (or at least a portion of a length of the support structure 320 in the x-axis direction described above with reference to FIG. 7) is disposed in a first row of the structure substrate 310, and a second modified support structure that has a same shape as the first modified support structure and that has an opposite curved surface arrangement direction is disposed in a second row. As another example, the first modified support structure (or the second modified support structure) may include, for example, a form in which first support structures 321a (or second support structures 321b) having a specific size are continuously connected. Alternatively, the electronic device 101 may include a plurality of first support structures 321a and at least one first modified support structure, and a plurality of second support structures 321b and at least one second modified support structure. According to an embodiment, a specific auxiliary structure that is disposed in the electronic device 101 may include support structures each having a first surface that faces a structure substrate and has a rectangular shape (e.g., a square) of a specific size and that are provided as a plurality of individual units, and may include a structure in which the support structures are arranged in a grid form on one structure substrate or a plurality of structure substrates. As an example, structures having a relatively small size may be gathered to form one auxiliary structure, each of which includes a structure substrate and a support structure having a specific size corresponding to a size of one actuator described above with reference to FIG. 8, as compared to the auxiliary structure described above with reference to FIG. 5. According to an embodiment, a size of one actuator described above with reference to FIG. 8 may vary depending on at least one of a size, a type, and an arrangement form of the support structure.

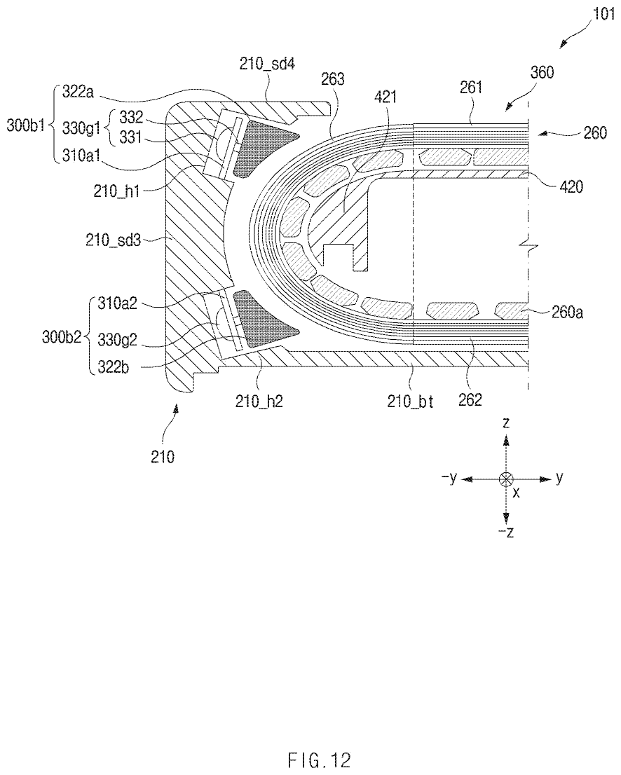

FIG. 12 is a view illustrating an example of an electronic device including a third-type auxiliary structure according to an embodiment of the disclosure.

Referring to FIGS. 2 to 12, the electronic device 101 may include a display assembly 360, a second housing 420, a first case 210, a third-type auxiliary structure 300b1 (or a structure, a third-type structure), and a fourth-type auxiliary structure 300b2 (or a structure, a fourth-type structure). Additionally or alternatively, as described above with reference to FIG. 4, the electronic device 101 may further include at least some of other components in addition to the above-described components.

The state of the illustrated drawing corresponds to a view illustrating an example of the first arrangement state, in which the third-type auxiliary structure 300b1 and the fourth-type auxiliary structure 300b2 are spaced apart from the display assembly 360 so that the electronic device 101 is deformed from the retracted position to the extended position. When the electronic device 101 is positioned in the second arrangement state corresponding to the retracted position or the extended position, at least a portion of the third-type auxiliary structure 300b1 and the fourth-type auxiliary structure 300b2 may be formed to be in contact with (or to be close within a predefined first distance to) at least a portion of the display assembly 360.

The third-type auxiliary structure 300b1 may include a first structure substrate 310a1, a third support structure 322a, and a first actuator 330g1 (or a first actuator group).

A width of the first structure substrate 310al may have, for example, half a size of a width (or a z-axis length) of the structure substrate 310 described above with reference to FIG. 6. Alternatively, a length of the first structure substrate 310al in the x-axis direction may be formed to be the same as or similar to a length of the structure substrate 310 in the x-axis direction described above with reference to FIG. 6, and a length of the first structure substrate 310al in the z-axis direction may be formed to be smaller than a length of the structure substrate 310 in the z-axis direction described above with reference to FIG. 6. The first structure substrate 310al may have, for example, a size at which one first actuator 330g1 may be disposed. Alternatively, the first structure substrate 310al may have a size at which a plurality of first actuators 330g1 (e.g., a first actuator group in which the plurality of actuators are disposed to form one row) may be disposed.

The third support structure 322a may have at least one of a size and a shape that is the same as or similar to at least one of a size and a shape of the second support structure 321b described above with reference to FIG. 11. The third support structure 322a may have a curved surface (or a curvature) (e.g., a shape in which at least a portion is concave in the z-axis direction) corresponding to a portion of the first extension area 263 of the display assembly 360 (e.g., a portion that forms a specific curvature and at least a portion of which is convex in the z-axis direction).

The first actuator 330g1 may have a structure that is the same as a structure of the actuator 330 described above with reference to FIG. 8. According to an embodiment, in the first arrangement state, the first actuator 330g1 may be disposed such that the base portion 331 has a state, in which the base portion 331 is located on one surface (e.g., one surface in the −y-axis direction or one surface in a diagonal direction between the −z-axis and the y-axis) with respect to the first structure substrate 310a1, a portion of the pillar portion 332 is located inside the base portion 331, and the remaining portion protrudes by a first length to an opposite surface (e.g., in the y-axis direction or a diagonal direction between the −z-axis and the y-axis) with respect to the hole of the structure substrate 310 and the first structure substrate 310a1. The first actuator 330g1 may be deformed to the second arrangement state in response to a control of the processor (e.g., the processor 120 of FIG. 1) of the electronic device 101. In the second arrangement state, the base portion 331 of the first actuator 330g1 may have a state in which the base portion 331 protrudes to an opposite surface (e.g., in the y-axis direction or a diagonal direction between the −z-axis and the y-axis) with respect to the first structure substrate 310a1, and the pillar portion 332 may protrude from one point of the base portion 331 toward the opposite surface by a second length that is longer than the first length. In the second arrangement state, the third support structure 322a of the third-type auxiliary structure 300b1 may be in contact with (or be close within a predesigned specific distance to) a specific portion (e.g., an upper end portion (or a portion in the z-axis direction) of the first extension area 263 or a portion of the first extension area 263, which is disposed to be close to the first screen area 261) of the display assembly 360.

The above-described third-type auxiliary structure 300b1 may be disposed in a first structure arrangement recess 210_h1 that is formed between the first case lower end 210_sd3 and the first case upper end 210_sd4. The electronic device 101 may further include a fixing means so that the third-type auxiliary structure 300b1 is fixed to the first structure arrangement recess 210_h1. The first structure arrangement recess 210_h1 may include, for example, a shape that is opened in a diagonal direction between the −z-axis and the y-axis. The illustrated drawing illustrates an example of a cross section of one side of the first case 210, and the first structure substrate 310al of the third-type auxiliary structure 300b1 may be manufactured in a module form having a substrate shape having a size that is similar to a size of the first actuator 330g1. When the third-type auxiliary structure 300b1 includes a plurality of modules, the third-type auxiliary structure 300b1 may be disposed in the first case 210 to be spaced apart from each other at a specific interval. In this regard, the first structure arrangement recess 210_h1 may include a plurality of recesses that are disposed inside the first case 210 to be spaced apart from each other by a specific interval. A wire that electrically connects the third-type auxiliary structures 300b1 may be disposed inside the first case 210 of the electronic device 101 (e.g., on a bottom surface of the case groove 210_rc of FIG. 5). Alternatively, the first structure substrate 310al may have a length that is the same as or similar to an x-axis length of the structure substrate 310 described above with reference to FIG. 6, and a z-axis length thereof may be formed to have a length (e.g., half a size of the structure substrate 310) that is smaller than a z-axis length of the structure substrate 310 described above with reference to FIG. 6. In this case, a wire that connects the third-type auxiliary structures 300b1 may be included on (or inside) the first structure substrate 310a1. When the first structure substrate 310al is formed as one substrate having a length corresponding to an x-axis length of the first case lower end 210_sd3, the first structure arrangement recess 210_h1 may include one recess, into which the first structure substrate 310al may be inserted, inside the first case lower end 210_sd3.

The fourth-type auxiliary structure 300b2 may include a second structure substrate 310a2, a fourth support structure 322b, and a second actuator 330g2 (or a second actuator group). The fourth-type auxiliary structure 300b2 has a structure that is the same as or similar to that of the third-type auxiliary structure 300b1, and an arrangement position thereof may be a position that is symmetrical to the third-type auxiliary structure 300b1. As an example, the fourth support structure 322b of the fourth-type auxiliary structure 300b2 may be disposed to face a diagonal direction between the z axis and the y axis, at least a portion thereof may be disposed in the second structure arrangement recess 210_h2 in the first arrangement state, and in the second arrangement state, may be disposed to be in contact with (or be close within a predefined specific distance to) another portion (e.g., a lower end portion of the first extension area 263 or a portion of the first extension area 263, which is disposed close to the second extension area 262) of the display assembly 360.

As another example, the third-type auxiliary structure 300b1 and the fourth-type auxiliary structure 300b2 may include different structures. As an example, the third-type auxiliary structure 300b1 may include a first number of third support structures 322a that have a length in an x-axis direction of a first size and a first number of first structure substrates 310a1, and the fourth-type auxiliary structure 300b2 may include a second number of fourth support structures 322b that have a length in the x-axis direction that is smaller than the first size, and that is greater than the first number, and a second number of second structure substrates 310a2. Alternatively, the third-type auxiliary structures 300b1 may include a plurality of individual modules that are disposed in the case groove 210_rc, and the fourth-type auxiliary structure 300b2 may include a structure in which one support structure is formed on one structure substrate.

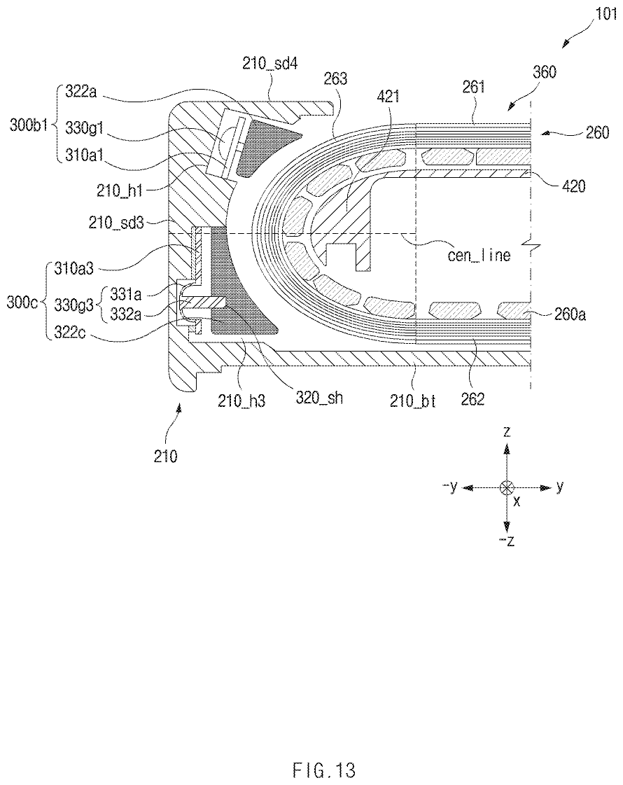

FIG. 13 is a view illustrating an example of an electronic device including a fifth-type auxiliary structure according to an embodiment of the disclosure.

Referring to FIGS. 2 to 13, an electronic device 101 according to an embodiment may include a display assembly 360, a second housing 420, a first case 210, and a fifth-type auxiliary structure 300c (or a structure, a fifth-type structure). Additionally or alternatively, the electronic device 101 may further include the third-type auxiliary structure 300b1 (or the fourth-type auxiliary structure 300b2). For example, although FIG. 13 illustrates the electronic device 101 that includes both the third-type auxiliary structure 300b1 and the fifth-type auxiliary structure 300c, the electronic device 101 may include only the fifth-type auxiliary structure 300c. The third-type auxiliary structure 300b1 and the first structure arrangement recess 210_h1 may include a shape that is the same as or similar to that of the third-type auxiliary structure and the first structure arrangement recess described above in FIG. 12.

The fifth-type auxiliary structure 300c may include a third structure substrate 310a3, a fifth support structure 322c, and a third actuator 330g3 (or a first actuator group).

The third structure substrate 310a3 may have a size that is smaller than a size of the structure substrate 310 described above in FIG. 6, and that is larger than a size of the first structure substrate 310al described above in FIG. 12, for example. As an example, the third structure substrate 310a3 may be formed to have a size of one half or more of a z-axis height of an inner recess of the first case 210. Alternatively, the third structure substrate 310a3 may be formed to have a z-axis length corresponding to a height of one half or more of a z-axis height of the display assembly 360. A plurality of the fifth-type auxiliary structures 300c may be disposed inside the first case 210, or one structure may be formed. Correspondingly, the third structure substrate 310a3 may include one substrate that is disposed inside the first case 210, or may include a plurality of substrates that are disposed to be spaced apart from each other at a specific interval. The third structure substrate 310a3 may include a wire for supplying power to the third actuator 330g3 and a hole for the third actuator 330g3 to be disposed.

The fifth support structure 322c may be formed to have a z-axis length that is smaller than a z-axis length of the support structure 320 described above in FIG. 7, and that is larger than a z-axis length of the first support structure 321a described above in FIG. 11 or a z-axis length of the third support structure 322a described above in FIG. 12. As an example, a size of one surface of the fifth support structure 322c in the −y-axis direction may be the same as or similar, within a specific error range, to a size of one surface of the third structure substrate 310a3. According to an embodiment, a z-axis height of the fifth support structure 322c may be formed to have a size of one half or more of a z-axis height of an inner recess of the first case 210. Alternatively, a z-axis height of the fifth support structure 322c may be formed to have a height of one half or more of a z-axis height of the display assembly 360.

The third actuator 330g3 may have a size and a structure that are the same as those of the actuator described above in FIG. 11 or 12. Alternatively, the third actuator 330g3 may include a base portion 331a and a pillar portion 332a that have sizes larger than those of a base portion and a pillar portion of the actuator described above in FIG. 11 or 12. The pillar portion 332a may be inserted into a support recess 320_sh that is formed on a rear surface of the fifth support structure 322c. The support recess 320_sh may be formed at a center-of-gravity position of a rear surface of the fifth support structure 322c. As an example, a size of the actuator may be different depending on at least one of a size, a position, and a direction of the support structure.

According to an embodiment, in the first arrangement state, at least a portion of the fifth support structure 322c may be disposed in the third structure arrangement recess 210_h3 and define a gap of a first size with one surface of the third structure substrate 310a3. In the second arrangement state, at least a portion of the fifth support structure 322c may protrude from the third structure arrangement recess 210_h3 in the y-axis direction, and define a gap of a second size that is larger than the first size with one surface of the third structure substrate 310a3. Alternatively, in the second arrangement state, at least a portion of the fifth support structure 322c may contact one portion (e.g., the first extension area 263) of the display assembly 360, or may have a state of being close within a predefined specific distance thereto. The fifth-type auxiliary structure 300c may be linearly moved in a direction parallel to a bottom part 210_bt of the first case 210. In this regard, the third structure arrangement recess 210_h3 may be formed to be engraved in the −y-axis direction inside the first case 210. In the second arrangement state and a retracted position state, the fifth support structure 322c may be disposed to support one half or more of the first extension area 263 (or a display curved area) of the display assembly 360, so that damage to the display assembly 360 may be prevented when an external impact occurs. In the second arrangement state and an extended position state, the fifth support structure 322c may support one half or more of the second extension area 262 (or a display curved area corresponding to a curved area 421 of the second housing 420), so that damage to the display assembly 360 may be prevented. The electronic device 101 may support an intermediate state between a maximum retracted position and a maximum extended position. Correspondingly, when the electronic device 101 is temporarily fixed in the intermediate state, the fifth support structure 322c may contact a specific area (e.g., a display curved area corresponding to the intermediate state) of the display assembly 360, so that damage to the specific area of the display assembly 360 may be prevented.

Meanwhile, in the above-described structure, although the third-type auxiliary structure 300b1 is disposed between the first case lower end 210_sd3 and the first case upper end 210_sd4, and the fifth-type auxiliary structure 300c is disposed on one side of the first case lower end 210_sd3, the disclosure is not limited thereto. For example, the fifth-type auxiliary structure 300c may be disposed at a position of the first case lower end 210_sd3 that is biased toward the first case upper end 210_sd4. In this case, the fifth-type auxiliary structure 300c may include a fifth support structure that is disposed in a direction opposite to a curved area arrangement direction of the fifth support structure 322c of the fifth-type auxiliary structure 300c that is currently illustrated. For example, the fifth-type auxiliary structure 300c may be disposed at positions of the display assembly 360, which are symmetrical to each other upward and downward (or the z-axis to the −z-axis) with respect to an imaginary transverse center line cen_line. Correspondingly, at least a portion of the fifth support structure 322c may be disposed close to the first case upper end 210_sd4, and in the second arrangement state, the fifth support structure 322c may block a gap between the first case upper end 210_sd4 and the display assembly 360.

The illustrated drawing illustrates an example of a cross section of one side of the first case 210, and the third structure substrate 310a3 of the fifth-type auxiliary structure 300c may be manufactured in a module form having a substrate shape having a size that is similar to a size of the third actuator 330g3. The fifth-type auxiliary structure 300c may include a plurality of modules, and correspondingly, the third structure arrangement recess 210_h3 may include a plurality of recesses that are disposed inside the first case 210 to be spaced apart from each other at a specific interval. A wire that electrically connects the fifth-type auxiliary structures 300c may be disposed inside the first case 210 of the electronic device 101 (e.g., on a bottom surface of the case groove 210_rc of FIG. 5). Alternatively, the fifth-type auxiliary structure 300c may include the third structure substrate 310a3 that has a length corresponding to an x-axis length of the first case lower end 210_sd3, and may include a plurality of third actuators 330g3 and one fifth support structure 322c.

Meanwhile, although examples of the auxiliary structures described above in FIGS. 2 to 13 have independent structures, respectively, and may be applied to the electronic device 101, the disclosure is not limited thereto. For example, at least some features of the auxiliary structure (e.g., 300) described in FIGS. 2 to 10 may be selectively applied to at least some auxiliary structures among the auxiliary structures 300a, 300b1, 300b2, and 300c described in FIGS. 11 to 13. Alternatively, various forms of the auxiliary structures 300a, 300b1, 300b2, and 300c described in FIGS. 11 to 13 may be combined with each other. For example, at least one of the auxiliary structures 300a, 300b1, 300b2, and 300c of the disclosure may include a structure in which one actuator is disposed on one structure substrate as a separate module, or may include a structure in which a plurality of actuators is disposed on one structure substrate. Furthermore, a form of a support structure included in the auxiliary structures 300a, 300b1, 300b2, and 300c of the disclosure may be provided in a form that is separated to correspond to a size of one actuator, or in a form that has one body that supports a plurality of actuators. As an example, the support structure may be provided in a grid form that is divided in a longitudinal direction and a lateral direction, and a grid form that may be applied to one electronic device 101 may include at least one type. For example, support structures (e.g., at least one among the support structures described in FIGS. 11 to 13) that have different grid forms may be applied to one electronic device 101.

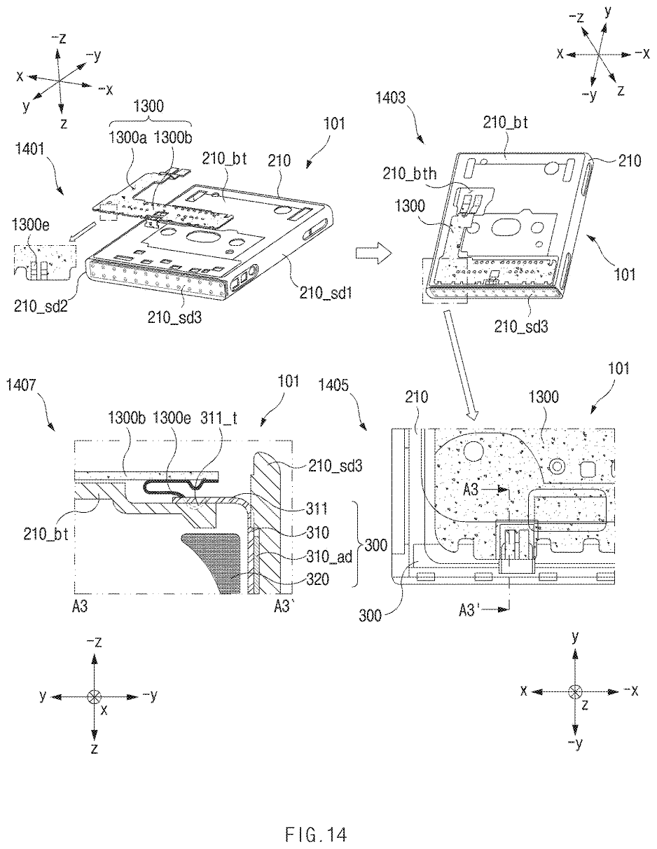

FIG. 14 is a view illustrating an example of a first printed circuit board connected to an auxiliary structure according to an embodiment of the disclosure. In FIG. 14, state 1401 corresponds to a view illustrating an example of a form in which a first printed circuit board 1300 and the first case 210 are separated, and state 1403 corresponds to a view illustrating an example of a form in which the first printed circuit board 1300 is disposed on a rear surface (e.g., a rear surface of the first case bottom part 210_bt) of the first case 210. State 1405 corresponds to a view illustrating an example of one portion of the first printed circuit board 1300 that is disposed on the first case 210, and state 1407 corresponds to a view illustrating an example of a cross section taken along cutting line A3-A3′ in state 1405. In FIG. 14, a structure to which the first-type auxiliary structure 300 is applied is illustrated, however, the disclosure is not limited thereto. For example, the same may be applied to other types of auxiliary structures described above in FIGS. 11 to 13, and in this regard, at least one of the structure substrates described in FIGS. 11 to 13 may include a structure corresponding to a board connection portion 311.

Referring to FIGS. 2 to 14, the first case 210 may include a first case bottom part 210_bt, a first case right part 210_sd1, a first case left part 210_sd2, a first case lower end 210_sd3, and a first case upper end 210_sd4. The first printed circuit board 1300 may include, for example, a first PCB portion 1300a that has a length in a first direction (e.g., the y-axis direction) that is longer than a length in a second direction (e.g., the x-axis direction), and a second PCB portion 1300b that is connected to the first PCB portion 1300a and that has a length in the second direction that is longer than a length in the first direction. A PCB terminal 1300e that may be electrically connected to the first-type auxiliary structure 300 may be disposed at a portion of the second PCB portion 1300b. The PCB terminal 1300e may be disposed, for example, in a direction of a surface of one surface of the second PCB portion 1300b that faces a front surface of the first case bottom part 210_bt, and may be disposed at a position that may face a board connection portion 311 of the first-type auxiliary structure 300. In the illustrated drawing, although the PCB terminal 1300e is illustrated as having two terminals that are provided in a C-clip form, embodiments of the disclosure are not limited to the number or a form of the PCB terminal 1300e. Referring to a cross section taken along cutting line A3-A3′ of state 1405, the first-type auxiliary structure 300 includes a structure substrate 310 and a support structure 320, and referring to the auxiliary structure described above in FIGS. 2 to 13, the first-type auxiliary structure 300 may include at least one actuator. Additionally, the first-type auxiliary structure 300 may further include a fixing means 310_ad (e.g., a coupling member, an adhesive member, an adhesive layer) for fixing the structure substrate 310 to the first case lower end 210_sd3.

The first printed circuit board 1300 may be held (or attached, fixed, or disposed) on a rear surface (e.g., a surface observed in the −z-axis direction) of the first case bottom part 210_bt. At least a portion of the first case bottom part 210_bt may include at least one hole (e.g., 210_bth) that passes through front and rear surfaces (e.g., a surface in the z-axis or −z-axis direction), and, through the at least one hole (e.g., 210_bth), at least a portion of the first printed circuit board 1300 may be disposed on a front surface (a surface that may be observed from the z-axis direction) of the first case bottom part 210_bt. As an example, through the hole 210_bth formed in the first case bottom part 210_bt, a portion of the first printed circuit board 1300 may be exposed to a front surface of the first case bottom part 210_bt, and the portion of the first printed circuit board 1300, which is exposed to the front surface, may contact a portion of the second printed circuit board 1500 electrically. Similarly, through the hole formed in the first case bottom part 210_bt, at least a portion of the board connection portion 311 of the first-type auxiliary structure 300 may be exposed toward a rear surface (e.g., a surface that faces the −z-axis direction) of the first case bottom part 210_bt. The PCB terminal 1300e may be electrically connected to the terminal 311_t formed at the board connection portion 311 of the first-type auxiliary structure 300. The terminal 311_t formed at the board connection portion 311 may be formed to have a number that is the same as or similar to a number of terminals formed at the PCB terminal 1300e.

The first printed circuit board 1300 may receive power from a battery (e.g., the battery 205 of FIG. 4), and may transfer the supplied power to the terminal 311_t of the board connection portion 311 through the PCB terminal 1300e. The power that is transferred through the terminal 311_t of the board connection portion 311 may be supplied to a plurality of actuators (e.g., the plurality of actuators 330 of FIG. 5) through a wire that is disposed on the structure substrate 310. When power is supplied, the first-type auxiliary structure 300 may move the support structure 320 in a first direction to adjust a gap between the support structure 320 and the structure substrate 310 to a first size, and when the supply of the power is cut off, the first-type auxiliary structure 300 may move the support structure 320 in a second direction, which is an opposite direction to the first direction, to adjust the gap between the structure substrate 310 and the support structure 320 to a second size that is smaller (or larger) than the first size. A size of a gap that is formed between the support structure 320 and the structure substrate 310 in a state in which power is supplied or cut off may vary depending on a design. As an example, when the supply of power is cut off, a gap between the support structure 320 and the structure substrate 310 may become a first size (or a minimum size that the first-type auxiliary structure 300 may form), and when power is supplied, the gap between the support structure 320 and the structure substrate 310 may become a second size (or a maximum size that the first-type auxiliary structure 300 may form). Alternatively, when the supply of power is cut off, a gap between the display assembly (e.g., the display assembly 360 of FIG. 4) of the electronic device 101 and the support structure 320 may become a second size (or a maximum size that the first-type auxiliary structure 300 may form), and when power is supplied, the gap between the display assembly (e.g., the display assembly 360 of FIG. 4) and the support structure 320 may become a first size (or a minimum size that the first-type auxiliary structure 300 may form or a state in which the gap is 0, that is, a contact state).

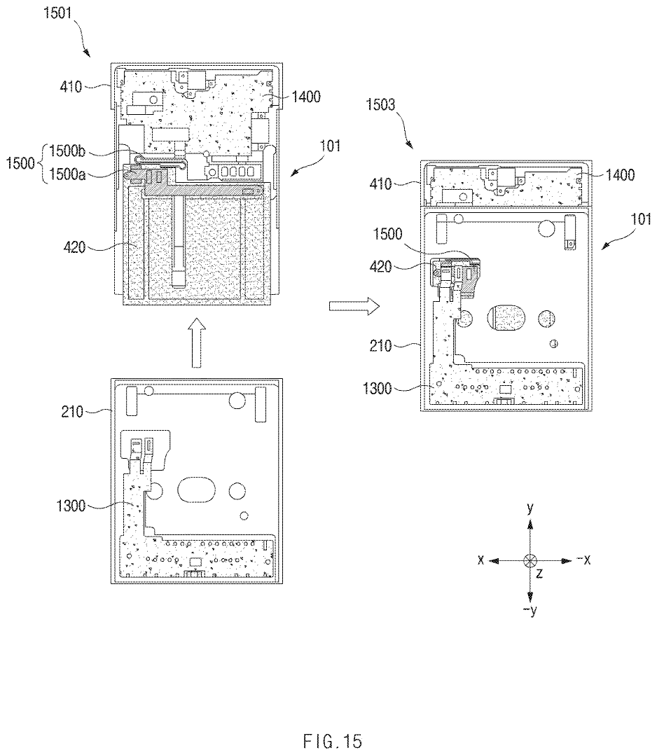

FIG. 15 is a view illustrating an example of a connection relationship of a first printed circuit board and other printed circuit boards according to an embodiment of the disclosure. In FIG. 15, state 1501 illustrates an example of a form, in which the first case 210, the first housing 410, and the second housing 420 are separated, and state 1503 illustrates an example of a form, in which the first case 210, the first housing 410, and the second housing 420 are coupled to each other.

Referring to FIGS. 2 to 15, the electronic device 101 may include the first case 210, the first housing 410, the second housing 420, the first printed circuit board 1300, the second printed circuit board 1500, and the third printed circuit board 1400. The second housing 420 may be positioned on a rear surface of the first housing 410, and the first case 210 may be disposed to cover at least a portion of the second housing 420. The first case 210 and the second housing 420 may be linearly moved in the first direction or the second direction (e.g., the −y-axis direction or the y-axis direction), and correspondingly, the first case 210 may be linearly moved in the first direction or the second direction. Depending on an observation point, the first case 210 and the second housing 420 may be fixed, and the first housing 410 may be linearly moved in the second direction or the first direction (e.g., the y-axis direction or the −y-axis direction).

As described above with reference to FIG. 14, at least a portion of the first printed circuit board 1300 connected to the auxiliary structure (e.g., the first-type auxiliary structure 300) may be disposed on a rear surface (e.g., a surface observed from the −z-axis direction) of the first case 210. The first case 210 may include at least one hole that is used for connecting at least a portion of the first printed circuit board 1300 and other structures. For example, the first-type auxiliary structure 300 may be disposed in the first case 210, and the board connection portion 311 of the structure substrate 310 of the first-type auxiliary structure 300 may be electrically connected to the PCB terminal 1300e of the first printed circuit board 1300. An end of the first printed circuit board 1300, which extends in the y-axis direction, may include a connection structure that may be connected to the second printed circuit board 1500. For example, a one-side periphery of the first printed circuit board 1300 may include at least one first connector that is disposed to face the z-axis direction.

The second printed circuit board 1500 (or a connection printed circuit board) may include a first portion 1500a that is disposed on one side of a rear surface (e.g., a surface that faces the −z-axis direction) of the second housing 420, and a second portion 1500b that is disposed on the first housing 410. The first portion 1500a may be electrically connected to the second portion 1500b, and may be fixed onto the second housing 420. The first portion 1500a may, for example, be electrically coupled to the first printed circuit board 1300. According to an embodiment, the first portion 1500a may include a second connector that is disposed toward the −z-axis direction, and may be electrically connected to the first connector formed at an end of a portion of the first printed circuit board 1300, which extends to a y-axis periphery. The second portion 1500b may be electrically connected to the first portion 1500a, and may be configured such that at least a portion of an arrangement thereof is changed in response to a movement of the second housing 420. As an example, at least a portion of the second portion 1500b may include a corrugated shape or a folded shape. At least a portion of the second portion 1500b may be disposed such that it is unfolded when the second housing 420 is moved in the −y-axis direction, and is folded when the second housing 420 is moved in the y-axis direction. As an example, at least a portion of the second portion 1500b may be formed of a ductile material. Alternatively, a portion of the second portion 1500b may be formed as a rigid type, and a bendable portion may be formed of a ductile material. Another portion of the second portion 1500b may be electrically connected to the third printed circuit board 1400 (or a main printed circuit board). In this regard, a third connector may be disposed at one end of the second portion 1500b, and the third connector disposed at the second portion 1500b may be electrically connected to a fourth connector disposed at the third printed circuit board 1400.

The electronic device 101 having the above-described structure may receive power of the battery 205 at the third printed circuit board 1400, and, in response to control of a processor that is disposed on the third printed circuit board 1400, the received power of the battery 205 may be transferred to the first-type auxiliary structure 300 through the third printed circuit board 1400, the second printed circuit board 1500, and the first printed circuit board 1300.

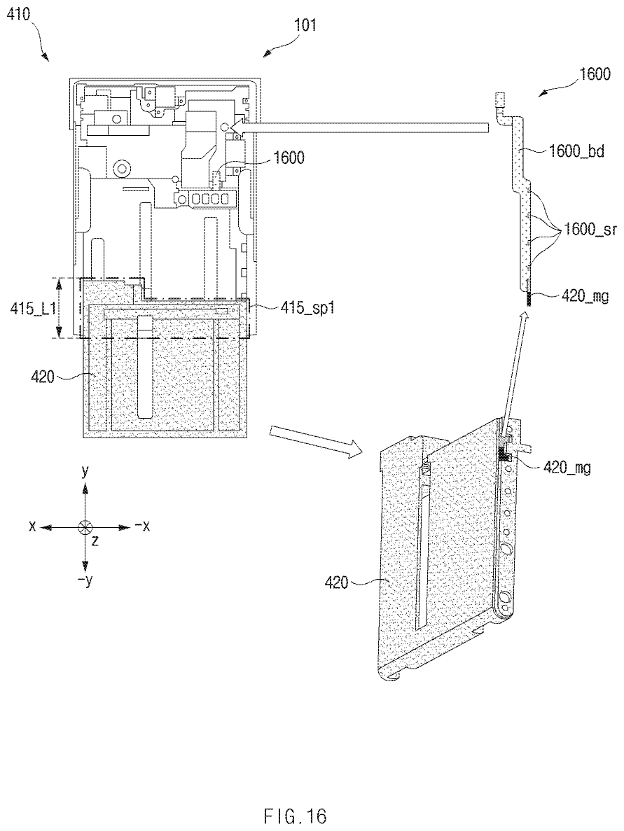

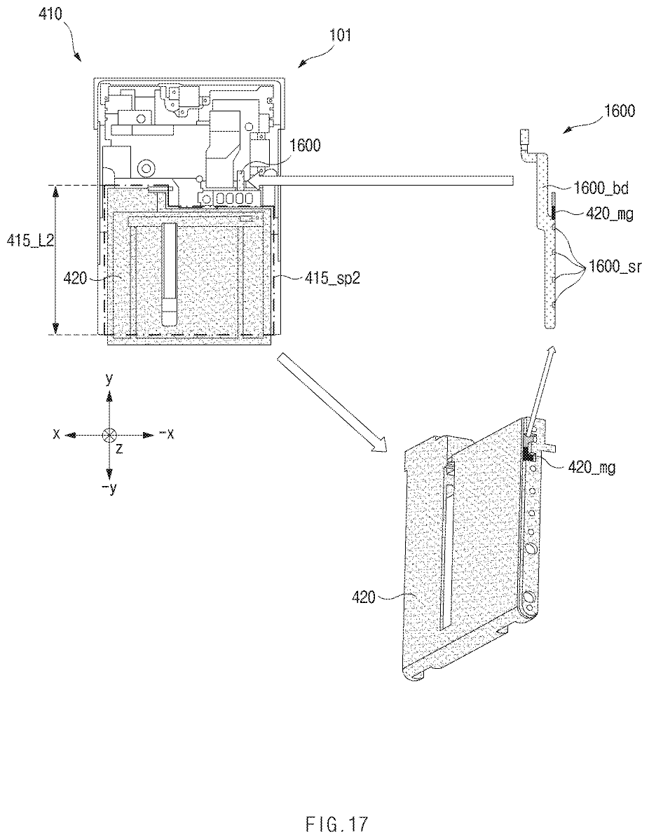

FIG. 16 is a view illustrating a first state related to sliding detection of an electronic device according to an embodiment of the disclosure, and FIG. 17 is a view illustrating a second state related to sliding detection of the electronic device according to an embodiment of the disclosure.

Referring to FIGS. 2 to 17, the electronic device 101 may include at least the first housing 410, the second housing 420, and the fourth printed circuit board 1600. At least a portion of the second housing 420 may be coupled on the first housing 410 (e.g., on a surface that faces the −z-axis direction) such that the second housing 420 is movable in the y-axis direction or the −y-axis direction. For example, as illustrated in FIG. 16, when observed from the z-axis direction (or the −z-axis direction), the electronic device 101 may have a first state in which a size 415_sp1 of an overlapping area of the first housing 410 and the second housing 420 (or a length 415_L1 of one side of the overlapping area of the first housing 410 and the second housing 420) is a first size, and, as illustrated in FIG. 17, when observed from the z-axis direction (or the −z-axis direction), may have a second state in which a size 415_sp2 of the overlapping area of the first housing 410 and the second housing 420 (or a length 415_L2 of one side of the overlapping area of the first housing 410 and the second housing 420) is a second size that is greater than the first size. In the first state, a certain range of a −y-axis periphery of the first housing 410 and a certain range of a y-axis periphery of the second housing 420 may be disposed to overlap each other with respect to the z-axis direction. In the first state, a certain range that includes a central portion of the first housing 410 and a certain range that includes a central portion of the second housing 420 may be disposed to overlap each other with respect to the z-axis direction.

At least a portion of the fourth printed circuit board 1600 may be disposed on one surface of the first housing 410 (e.g., a surface that faces the −z-axis direction). At least a portion of the fourth printed circuit board 1600 may be electrically connected to at least one of the first printed circuit board 1300, the second printed circuit board 1500, or the third printed circuit board 1400 described above. In the following description, a structure in which the third printed circuit board 1400 and the fourth printed circuit board 1600 are electrically connected will be described as an example. The fourth printed circuit board 1600 may include a plurality of sensors 1600_sr. The plurality of sensors 1600_sr (or each of the plurality of sensors 1600_sr) may sense a change in a magnetic flux of the magnet member 420_mg. As an example, the plurality of sensors 1600_sr may sense a change in the magnetic flux when the magnet member 420_mg approaches or when the magnet member 420_mg moves away. The plurality of sensors 1600_sr may transfer the sensed change in the magnetic flux to the third printed circuit board 1400 through a wire that is formed on a board body 1600_bd. Meanwhile, as illustrated, the magnet member 420_mg may be disposed at one side of the second housing 420 (e.g., one side of a side wall in the −x-axis direction). The magnet member 420_mg may have a relative position in the first housing 410 changed according to a movement of the second housing 420. As an example, according to a movement of the second housing 420, the magnet member 420_mg may be moved, and, according to the movement of the magnet member 420_mg, the plurality of sensors 1600_sr disposed on the fourth printed circuit board 1600 may sense a change in the magnetic flux according to the movement of the magnet member 420_mg and may transfer the sensed change to the third printed circuit board (e.g., the third printed circuit board 1400 of FIG. 15).

A processor that is disposed on the third printed circuit board (e.g., the third printed circuit board 1400 of FIG. 15) may determine a current state of the electronic device 101 based on the transferred change in the magnetic flux. For example, when a change in the magnetic flux indicating that the magnet member 420_mg is disposed at a −y-axis periphery of the fourth printed circuit board 1600 is received from the plurality of sensors 1600_sr, the processor may determine whether a state of the electronic device 101 is an extended position state as illustrated in FIG. 16 or a retracted position state as illustrated in FIG. 17. Additionally or alternatively, the processor may sense that a state of the electronic device 101 is changed from a retracted position state to an extended position state or from an extended position state to a retracted position state through the change in the magnetic flux provided by the plurality of sensors 1600_sr. As an example, when a change in the magnetic flux sensed by a sensor disposed at a y-axis periphery of the fourth printed circuit board 1600 occurs, the processor may determine that a state is changed from a retracted position state to an extended position state. Alternatively, when a change in the magnetic flux sensed by a sensor disposed at a −y-axis periphery of the fourth printed circuit board 1600 occurs, the processor may determine that a state is changed from an extended position state to a retracted position state.

The arrangement of the printed circuit boards related to the power supply described above with reference to FIGS. 14 and 15 may be applied to an electronic device to which at least one of the auxiliary structures described above with reference to FIGS. 2 to 13 is applied. Similarly, a function of sensing a change in a state of the electronic device 101, contraction, or an extended position state described above with reference to FIGS. 16 and 17 may be applied in the same or similar manner to an electronic device to which at least one of the auxiliary structures described above with reference to FIGS. 2 to 13 is applied. Furthermore, sensing of the state of the electronic device may be equally applied even in an arrangement environment of the printed circuit boards applied in FIGS. 14 and 15.

As described above, according to various embodiments of the disclosure, by disposing an auxiliary structure (e.g., a damping structure) that is capable of behavior in a curved area of the display assembly 360 (e.g., a display curved area), operability of the display assembly 360 may be secured and panel scratches may be prevented by maintaining a gap during an operation in which a state is changed from a retracted position to an extended position or from an extended position to a retracted position, and defects of the display 260 and scratch defects due to foreign substance inflow may be improved by directly supporting the display assembly 360 (or the display 260) while being fixed in the retracted position or the extended position and preventing damage to the display assembly 360 due to a drop impact or an external impact.

According to an embodiment of the disclosure, a rollable electronic device (or an electronic device) may include a housing that includes the first housing 410 and the second housing 420 that is configured to movably engage with the first housing 410 between a retracted position and an extended position, a display assembly 360 that is coupled to the first housing 410 and the second housing 420 such that a size of an area that is visible from a front side of the housing is changed as the housing is moved between the retracted position and the extended position, a first case 210 that is disposed on one side of the housing and includes a case groove 210_rc, and an auxiliary structure 300 that is disposed in the case groove 210_rc and is disposed toward at least a portion of a display curved area of the display assembly 360, wherein the auxiliary structure 300 may include a structure substrate 310 that is located in the case groove 210_rc, a support structure 320 that is disposed toward one surface of the structure substrate 310, and a plurality of actuators 330 that are at least partially disposed on the structure substrate 310 and that move the support structure 320 in a first direction that faces the display assembly 360 or in a second direction that is an opposite direction to the first direction.

The display assembly 360 may include an extended portion that is exposed in an extended position state and is covered in a retracted position state, and a fixed portion that is connected to the extended portion and is fixedly exposed.

According to an embodiment, the electronic device may further include a battery, and the structure substrate 310 may include a board connection portion that has a terminal formed to receive power from the battery and a wire that transfers the power to the plurality of actuators 330.

According to an embodiment, when power is supplied, the support structure 320 may be moved in the first direction by the plurality of actuators 330.

According to an embodiment, when the power is cut off, the support structure 320 may be moved in the second direction from the display assembly 360 by the plurality of actuators 330.

According to an embodiment, when the power is cut off, the support structure 320 may be moved in the first direction by the plurality of actuators 330.

According to an embodiment, when power is supplied, the support structure 320 may be moved in the second direction from the display assembly 360 by the plurality of actuators 330.

According to an embodiment, at the retracted position or the extended position, the support structure 320 may have a contact state with the display assembly 360.

According to an embodiment, the support structure 320 may be disposed such that it closes at least a portion of a gap between the display assembly 360 and the first case 210 at the retracted position or the extended position.

According to an embodiment, while the state is changed from the retracted position to the extended position or from the extended position to the retracted position, a gap having a first size may be formed between the display assembly and the support structure.

According to an embodiment, the support structure 320 may include a curved surface that has a center that is concave with respect to a periphery, and a curvature of the curved surface of the support structure 320 may be formed to be the same as or similar to at least a portion of a curvature of the display curved area.

According to an embodiment, the support structure may include a central area, a structure upper area that is formed on a front side with respect to the central area and that protrudes more than the central area, and a structure lower area that is formed on a lower side with respect to the central area and that protrudes more than the central area.

According to an embodiment, at least a portion of the structure upper area may be formed of a first material that includes a fiber, and the central area may be formed of a second material that has a ductility higher (or greater) than that of the first material.

According to an embodiment, the central area and the structure lower area may be formed of a first material that has a shock absorbing function, and the structure upper area may be formed of a second material that has a dustproof function.

According to an embodiment, the support structure may include a plurality of layers, and a first layer among the plurality of layers may be formed of a first material that has a shock absorbing function, and a second layer among the plurality of layers may be formed of a second material that has a dustproof function.

According to an embodiment, the first layer may be disposed in a direction that faces the structure substrate, and the second layer may be disposed in a direction that faces the display assembly.

According to an embodiment, the structure substrate may include a plurality of holes, and each of the plurality of actuators may include a base portion that is disposed in a first surface direction of the structure substrate (or a direction toward a first surface of the structure substrate) and a pillar portion that is connected to the base portion and that protrudes in a second surface direction of the structure substrate (or a direction toward a second surface of the structure substrate) through one hole of the plurality of holes and is coupled to the support structure.

According to an embodiment, the base portion may protrude in a second surface direction of the structure substrate (or a direction toward a second surface of the structure substrate) when power is supplied or when power is cut off.

According to an embodiment, the auxiliary structure may include a first auxiliary structure that is disposed at an upper side of the case groove with respect to a front surface of the housing, and a second auxiliary structure that is spaced apart from the first auxiliary structure and that is disposed at the lower side of the case groove.

According to an embodiment, a size of the first support structure of the first auxiliary structure and a size of the second support structure of the second auxiliary structure may be the same, and a curved surface direction of the first support structure and a curved surface direction of the second support structure may be opposite to each other.

According to an embodiment, a height of the support structure included in the second auxiliary structure (e.g., a height in the z-axis direction, a height in a direction from the first case bottom part toward a front surface of the display assembly 360) may be formed to be greater than a half of a thickness of the display assembly.

An embodiment of disclosure and terms used herein are not intended to limit the technologies described in the disclosure to specific embodiments, and it should be understood that the embodiments and the terms include modification, equivalent, and/or alternative on the corresponding embodiment described herein. With regard to the description of drawings, similar components may be marked by similar reference marks/numerals. The terms of a singular form may include plural forms unless otherwise specified. In the disclosure, the expressions “A or B”, “at least one of A and/or B”, “A, B, or C”, or “at least one of A, B, and/or C”, and the like used herein may include any and all combinations of one or more of the associated listed items. Expressions such as “first,” or “second,” and the like, may express their components regardless of their priority or importance and may be used to distinguish one component from another component but is not limited to these components. When a certain component (e.g., a first component) is referred to as being “connected” or “coupled” (functionally or communicatively) to another component (e.g., a second component), it should be understood that the certain component may be directly connected to the other component or may be connected to the other component through another component (e.g., a third component).

According to the situation, the expression “adapted to or configured to” used herein may be interchangeably used as, for example, the expression “suitable for”, “having the capacity to”, “changed to”, “made to”, “capable of” or “designed to”. The expression “a device configured to” may mean that the device is “capable of” operating together with another device or other parts. For example, a “processor configured to (or set to) perform A, B, and C” may mean a dedicated processor (e.g., an embedded processor) for performing corresponding operations or a generic-purpose processor (e.g., a central processing unit (CPU) or an AP) which performs corresponding operations by executing one or more software programs which are stored in a memory device (e.g., the memory).

The term “module” used herein may include a unit, which is implemented with hardware, software, or firmware, and may be interchangeably used with the terms “logic”, “logical block”, “part”, “circuit”, or the like. The “module” may be an integrated component, a minimum unit for performing one or more functions, or a part thereof. The “module” may be implemented mechanically or electronically. For example, the module may include a well-known or to-be-developed application-specific integrated circuit (ASIC) chip, field-programmable gate arrays (FPGAs), or programmable logic device that perform any operations.

According to various embodiment, at least part of a device (e.g., modules or functions thereof) or a method (e.g., operations) may be, for example, implemented by instructions stored in a computer-readable storage media (e.g., a memory) in the form of a program module. The instruction, when executed by a processor (e.g., a processor), may cause the processor to perform a function corresponding to the instruction. The computer-readable recording medium may include a hard disk, a floppy disk, a magnetic media (e.g., a magnetic tape), an optical medium (e.g., a compact disc read only memory (CD-ROM) and a digital versatile disc (DVD), a magneto-optical media (e.g., a floptical disk)), an embedded memory, or the like. The one or more instructions may contain a code made by a compiler or a code executable by an interpreter.

Each element (e.g., a module or a program module) according to various embodiments may be composed of single entity or a plurality of entities, a part of the above-described sub-elements may be omitted or may further include other elements. Alternatively or additionally, some components (e.g., a module or a program module) may be combined with each other so as to form one entity, so that the functions of the components may be performed in the same manner as before the combination.

According to various embodiments, operations executed by modules, program modules, or other components may be executed by a successive method, a parallel method, a repeated method, or a heuristic method. Alternatively, at least some of the operations may be executed in another order or may be omitted, or any other operation may be added.

While the disclosure has been shown and described with reference to various embodiments thereof, it will be understood by those skilled in the art that various changes in form and details may be made therein without departing from the spirit and scope of the disclosure as defined by the appended claims and their equivalents.

What is claimed is:

1. An electronic device, comprising:
a housing including a first housing and a second housing, the second housing being configured to movably engage with the first housing between a retracted position and an extended position;
a display assembly coupled to the first housing and the second housing, wherein a size of an area of the display assembly visible from a front side of the housing changes as the second housing moves between the retracted position and the extended position, wherein the display assembly includes (i) an extended portion that is exposed in the extended position and obscured in the retracted position, and (ii) a fixed portion connected to the extended portion, the fixed portion being fixedly exposed;
a first case disposed toward one side of the housing, the first case including a case groove; and
a structure disposed within the case groove, the structure being disposed toward at least a portion of a display curved area of the display assembly,
wherein the structure includes:
a structure substrate located within the case groove,
a support structure disposed toward one side of the structure substrate, and
a plurality of actuators at least partially disposed on the structure substrate, the plurality of actuators being configured to move the support structure in a first direction toward the display curved area or a second direction opposite to the first direction.

2. The electronic device of claim 1, further comprising:
a battery,
wherein the structure substrate includes:
a board connection portion including a terminal for receiving power from the battery, and
a wire configured to transfer the power to the plurality of actuators.

3. The electronic device of claim 2, wherein the support structure is configured to move in the first direction by the plurality of actuators when the power is supplied.

4. The electronic device of claim 3, wherein the support structure is configured to move from the display assembly in the second direction by the plurality of actuators when the power is cut off.

5. The electronic device of claim 2, wherein the support structure is configured to move in the first direction by the plurality of actuators when the power is cut off.

6. The electronic device of claim 5, wherein the support structure is configured to move from the display assembly in the second direction by the plurality of actuators when the power is supplied.

7. The electronic device of claim 1, wherein the support structure is in contact with the display assembly in the retracted position or the extended position.

8. The electronic device of claim 7, wherein the support structure is arranged to close at least a portion of a gap between the display assembly and the first case in the retracted position or the extended position.

9. The electronic device of claim 1, wherein a gap of a first size is formed between the display assembly and the support structure when changing from the retracted position to the extended position or from the extended position to the retracted position.

10. The electronic device of claim 1,
wherein the support structure includes a curved surface, a center of the curved surface being more concave than a periphery of the curved surface,
wherein a curvature of the curved surface of the support structure is the same or similar to at least a portion of a curvature of the display curved area.

11. The electronic device of claim 1, wherein the support structure includes:
a central area;
an upper area of the support structure formed toward the front side of the housing based on the central area, the upper area protruding from the central area; and
a lower area of the support structure formed below the central area, the lower area protruding from the central area.

12. The electronic device of claim 11,
wherein at least a portion of the upper area is formed of a first material including fibers, and
wherein at least a portion of the central area is formed of a second material of higher ductility than the first material.

13. The electronic device of claim 11,
wherein the central area and the lower area are formed of a first material configured to provide shock absorption, and
wherein the upper area is formed of a second material configured to be dustproof.

14. The electronic device of claim 1,
wherein the support structure includes a plurality of layers,
wherein a first layer among the plurality of layers is formed of a first material configured to provide shock absorption, and
wherein a second layer among the plurality of layers is formed of a second material configured to be dustproof.

15. The electronic device of claim 14,
wherein the first layer is disposed in a direction toward the structure substrate, and
wherein the second layer is disposed in a direction toward the display assembly.

16. The electronic device of claim 1,
wherein the structure substrate includes a plurality of holes, and
wherein each of the plurality of actuators includes:
a base portion disposed toward a first side direction of the structure substrate, and
a pillar portion connected to the base portion, the pillar portion protruding toward a direction of a second surface of the structure substrate through a hole among the plurality of holes to be coupled to the support structure.

17. The electronic device of claim 16, wherein the base portion protrudes in the direction of the second surface of the structure substrate when power is supplied or power is cut off.

18. The electronic device of claim 1, wherein the structure further includes:
a first structure disposed at an upper side of the case groove with respect to the front side of the housing; and
a second structure spaced apart from the first structure, the second structure being disposed at a lower side of the case groove.

19. The electronic device of claim 18,
wherein a size of a first support structure of the first structure and a size of a second support structure of the second structure are the same, and
wherein a curved direction of the first support structure and a curved direction of the second support structure are opposite.

20. The electronic device of claim 18, wherein a height of a second support structure of the second structure is greater than half of a thickness of the display assembly.
